(19) United States
(12) Patent Application Publication
(10) Pub. No.: US 2016/0300973 A1
(43) Pub. Date: Oct. 13, 2016

(54) VARIABLE RANGE PHOTODETECTOR WITH ENHANCED HIGH PHOTON ENERGY RESPONSE AND METHOD THEREOF

(71) Applicant: U.S. Army Research Laboratory ATTN: RDRL-LOC-I, Adelphi, MD (US)

(72) Inventors: Paul Shen, North Potomac, MD (US); Lee Ellen Rodak, Montgomery VIllage, MD (US); Chad Stephen Gallinat, Washington, DC (US); Anand Venktesh Sampath, Montgomery Village, MD (US); Michael Wraback, Germantown, MD (US)

(73) Assignee: U.S. Army Research Laboratory ATTN: RDRL-LOC-I, Adelphi, MD (US)

(21) Appl. No.: 15/180,397

(22) Filed: Jun. 13, 2016

Related U.S. Application Data
(63) Continuation-in-part of application No. 14/285,964, filed on May 23, 2014, now Pat. No. 9,379,271.
(60) Provisional application No. 61/827,079, filed on May 24, 2013.
(60) Provisional application No. 62/174,710, filed on Jun. 12, 2015.

(51) Int. Cl. H01L 31/107; H01L 31/0304; H01L 31/0296; H01L 31/0352; H01L 31/0336; H01L 31/18

(52) U.S. Cl. CPC H01L 31/1075; H01L 31/0336; H01L 31/18; H01L 31/0296; H01L 31/03529; H01L 31/03044

(57) ABSTRACT

A photodiode comprising a substrate; first semiconducting region; first contact; second region comprising an absorption region for the photons having a predetermined energy range; the second region being formed of a semiconductor having a high surface or interface recombination velocity; a third semiconducting region transparent at the predetermined photon energy range suitable for making an operative connection to a second contact; the second and third regions forming a second interface; the first and second regions forming a first interface; the second region being configured such that biasing the photodiode results in depletion of the second region from the first interface to the second interface or at least one of the absorption depth and the sum of the absorption depth and diffusion length from the second interface; the depletion resulting in the creation of an electric field whereby photogenerated carriers are collected by drift and a method of making the foregoing.

### CROSS-REFERENCE TO RELATED APPLICATIONS

This application claims priority of U.S. patent application Ser. No. 14/285,964, filed May 23, 2014, entitled “Variable Range Photodetector and Method Thereof” by Paul Shen, et al. (ARL 13-27), which was published as U.S. Pub. Appl. No. 2015/0311375 on Oct. 29, 2015, and which in turn claims priority to U.S. Provisional Patent Application Ser. No. 61/827,079 entitled “Photodetector With Polarization Induced Electron Filter And Method Thereof,” filed May 24, 2013, both of which are incorporated herein by reference. This application also claims priority to U.S. Provisional Patent Application Ser. No. 62/174,710 (15-27P) entitled “Enhanced Deep Ultraviolet Photodetector and Method Thereof” by Anand Sampath, Paul Shen, and Michael Wraback filed Jun. 12, 2015, herein incorporated by reference.

### GOVERNMENT INTEREST

The embodiments herein may be manufactured, used, and/or licensed by or for the United States Government without the payment of royalties thereon.

### BACKGROUND OF THE INVENTION

The present invention relates to types of photodiodes including avalanche photodiodes. In avalanche photodiodes (APDs) or photodetectors, incoming light is used to generate carriers (i.e., free electrons or holes) that are collected as current. Semiconductor materials are selected for photodiodes based upon the wavelength range of the radiation that is desired to be utilized or detected. APDs are operated at high reverse-bias voltages where avalanche multiplication takes place. The multiplication of carriers in the high electric field multiplication region in these structures gives rise to internal current gain. In linear mode operation, the output photo-induced current within the APD is linearly proportional to the illuminating photon flux, with the level of gain increasing with reverse bias. Importantly, the dark current that flows through the APD also tends to increase with increasing reverse bias. When biased sufficiently above the breakdown voltage, commonly referred to as excess bias, the APD can have sufficient internal gain so that an incident photon can induce a large and self-sustaining avalanche. This operating scheme is often referred to as Geiger mode and the diode along with enabling circuitry may be referred to as a single photon-counting avalanche photodiode (SPAD). In this mode, a non-photogenerated carrier may also be excited leading to avalanche current that is referred to as a dark count. In practice, the detection efficiency and dark count rate for the SPAD increase with increasing excess bias.

Deep ultraviolet (DUV) photodetectors sensitive at wavelengths shorter than 260 nm are useful in numerous medical and military applications, including chemical and biological identification and non-line of sight communications. Often, these applications require very low light level or single photon detection and, as a result, photomultiplier tubes (PMTs) are widely used. However, in addition to being large and fragile, photomultiplier tubes require the use of expensive filters to limit the bandwidth of detection.

Group III-nitride avalanche detectors can presumably be widely functional between 1900 nm and 200 nm (i.e. infrared to ultraviolet radiation). Generally, the binary alloys utilized in such semiconductor devices are Indium Nitride (bandgap of 0.65 eV corresponding to approximately 1900 nm), Gallium Nitride (band gap of 3.4 eV corresponding to approximately 365 nm) and Aluminum Nitride (bandgap of 6.1 eV corresponding to approximately 200 nm). By varying the relative mole fractions of these binaries, ternary or quaternary alloys may be composed that can achieve radiation absorption at intermediate wavelengths to the stated values.

III-Nitride semiconductors are commonly grown in the wurtzite crystal structure and are therefore a polar semiconductor as discussed by Ambacher in O. Ambacher, “Growth and Applications of Group III Nitrides, “J. Phys. D: Appl. Phys. 31 (1998) 2653-2710, herein incorporated by reference as though fully rewritten herein.

U.S. Pat. No. 6,326,654 to Ruden (hereinafter Ruden '654; hereby incorporated by reference) entitled “A Hybrid Ultraviolet Detector,” discloses a semiconductor material avalanche photodiode photodetector. The detector of Ruden '654 is an avalanche photodetector comprised of a group III-nitride semiconductor material, such as aluminum gallium nitride (AlₓGa₁₋ₓN), serving as a photon to charge carrier transducer, and an avalanche charge carrier multiplication region comprised of different semiconductor materials such as silicon (see abstract).

Aluminum gallium nitride (AlₓGa₁₋ₓN) photodetectors can take advantage of a sharp and tunable direct band gap to achieve high external quantum efficiency and avalanche multiplication in AlₓGa₁₋ₓN based p-i-n diodes has been reported. See, e.g., L. Sun, J. Chen. J. Li, H. Jiang, “AlGaN Solar-blind Avalanche Photodiodes With High Multiplication Gain,” Appl. Phys. Lett., 97, (191103) (2010) and P. Suvarna, M. Tungare, J. M. Leathersich, P. Agnihotri, F. Shahedipour-Sandvik, L. D. Bell, and S. Nikzad, “Design and Growth of Visible-Blind and Solar-Blind III-N APDs on Sapphire Substrates,” J. Electron. Mater. 42, 854 (2013)), both of which are herein incorporated by reference. However, this approach is limited by the difficulty in doping high AlN mole fraction alloys p-type, and a very large breakdown electric field for high AlN mole fraction that implies higher voltage operation and greater susceptibility to dark current associated with defects in the material.

Silicon Carbide (SiC) has emerged as an attractive material for DUV pin and avalanche photodetectors (APDs) due to their very low dark currents, small k factor, and high gain. Previously demonstrated APDs exhibit peak quantum efficiency (QE) of 60% at 268 nm and gain values reaching over 1000. However, the responsivity of these devices diminishes at wavelengths shorter than 260 nm due to increasing absorption and carrier generation in the illuminated doped layer of this device, and the short effective diffusion length of carriers in this region in the presence of a high density of surface states resulting in a high surface recombination velocity.

In general, the short wavelength response in pin detectors associated with detection of photons having energies much greater than the band gap of a semiconductor having a high density of surface states is hindered by the absorption of these photons near the surface of the heavily doped illuminated layer (p- or n-type). As a result, photo-generated carriers are trapped by surface band bending and are lost to surface recombination; the carrier transport in this layer may be characterized as diffusion, associated with the spatial gradient in photogenerated carriers, with a significantly reduced diffusion lengths for minority carriers over what would be expected in the bulk that can be described as a shorter effective diffusion length.

A number of groups have explored Schottky and metal-semiconductor-metal (MSM) 4H—SiC photodetectors to address this issue by enabling more efficient collection of carriers through photogeneration of these carriers primarily within the depletion region of the device. A. Sciuto, et al., “High responsivity 4H—SiC Schottky UV photodiodes based on the pinch-off surface effect.” Appl. Phys. Lett. 89, 081111 (2006) (herein incorporated by reference), report a peak QE of 29% at 255 nm for vertical Schottky diodes fabricated on n-type 4H—SiC using the pinch-off surface effect to increase the direct optical absorption area in the detector. X. Xin, F. Yan, T. W. Koeth, C. Joseph, J. Hu, J. Wu, and J. H. Zhao: “Demonstration of 4H—SiC UV single photon counting avalanche photodiode,” Electron. Lett., 41 1192 (2005) (herein incorporated by reference) reported large-area, 2×2 mm, n-4H—SiC Schottky diodes with QE of ˜20% at 200 nm. One challenge has been to realize a device design that mitigates the effects of surface recombination in these devices while maintaining sufficiently low dark currents at high bias to allow avalanche breakdown.

Therefore a need remains for low cost, compact, high sensitivity, low dark current/dark count rate photodetectors that operate in the ultraviolet spectrum and can offer a narrow and tunable bandwidth.

### SUMMARY

In accordance with the present invention, a preferred method comprises a method of making a photodiode which eliminates or minimizes surface recombination of photogenerated carriers generated by photons having a predetermined energy range comprising:

providing a substrate;
providing a first semiconducting region operatively associated with the substrate suitable for forming a contact thereon;
providing a first contact operatively associated with the first semiconducting region; providing a second region comprising an absorption region for the photons having a predetermined energy range; the second region being formed of a semiconductor having a high surface or interface recombination velocity;
providing a third semiconducting region transparent at the predetermined photon energy range suitable for making an operative connection to a second contact; providing a second interface between the second and third regions upon which the photons impinge;
the first semiconductor region and the second region forming a first interface such that the second region is depleted at the reverse bias point of operation; the depletion width in the second region varying with applied reverse bias; the minimal depletion width extending from the first interface to at least the sum of the absorption depth and the diffusion length from the second interface; the photodiode being configured such that biasing the photodiode results in depletion of the second region;
whereby the depletion results in the creation of an electric field and photogenerated carriers are collected by drift.

In accordance with the present invention, a preferred embodiment comprises a photodiode that eliminates or minimizes surface recombination of photogenerated carriers generated by photons having a predetermined energy range comprising:

a substrate;
a first semiconducting region operatively associated with the substrate suitable for forming a contact thereon;
a first contact operatively associated with the first semiconducting region;
a second region comprising an absorption region for the photons having a predetermined energy range; the second region being formed of a semiconductor having a high surface or interface recombination velocity;
a third semiconducting region transparent at the predetermined photon energy range suitable for making an operative connection to a second contact; the second and third regions forming a second interface upon which photons impinge;
the first semiconductor region and the second region forming a first interface; the second region being configured such that biasing the photodiode results in depletion of the second region at the reverse bias point of operation from the first interface to at least one of the absorption depth and the sum of the absorption depth and diffusion length from the second interface;
whereby the depletion results in the creation of an electric field and photogenerated carriers are collected by drift.

In accordance with the present invention, an alternate preferred embodiment comprises a photodiode that eliminates or minimizes recombination of photogenerated carriers generated by photons having a predetermined energy range comprising:

a substrate;

a first semiconducting region operatively associated with the substrate suitable for forming a contact thereon;

a first contact operatively associated with the first semiconducting region; a second region comprising an absorption region for the photons having a predetermined energy range; the second region being formed of a semiconductor having a high surface or interface recombination velocity;

a third semiconducting region transparent at the predetermined photon energy range suitable for making an operative connection to a second contact; the second and third regions forming a second interface upon which the photons impinge;

the first semiconductor region and the second region forming a first interface such that the second region is depleted at the reverse bias point of operation; the depletion width in the second region varying with applied reverse bias; the minimal depletion width extending from the first interface to at least the sum of the absorption depth and the diffusion length from the second interface; the photodiode being configured such that biasing the photodiode results in depletion of the second region;
whereby the depletion results in the creation of an electric field and photogenerated carriers are collected by drift.

As a further option, the second region comprises a semiconductor material having a band gap energy and the third region comprises semiconductor material having a band gap energy larger than the band gap energy of the second region. The third region is transparent at the predetermined photon energy range. Photons impinging the third region are absorbed in the second region generating carriers. The second region being configured such that biasing the photodiode results in depletion of the second region at the reverse bias point of operation from the first interface to (1) the absorption depth or (2) the sum of the absorption depth and the effective diffusion length from the second interface. See FIG. 26. Depletion occurring in the second region results in the creation of an electric field and photogenerated carriers are collected by drift.

These and other embodiments will be described in further detail below with respect to the following figures.

### BRIEF DESCRIPTION OF THE DRAWINGS

FIG. 1A is a schematic illustration of a preferred embodiment of the present invention.

FIG. 1B is a schematic illustration showing polarizations of layers 13, 14 and 15 of the preferred embodiment of FIG. 1A.

FIG. 2A is a schematic illustration of another preferred embodiment of the present invention.

FIG. 2B is a schematic illustration showing polarizations of layers 13, 14 and 16 of the preferred embodiment of FIG. 2A.

FIG. 3 is the measured DC spectral response of SiC/AlN/AlₓGa₍₁₋ₓ₎N nip photodiode at varying reverse bias voltage (closed figures). The DC spectral response for a homogeneous SiC pin photodiode is shown for comparison (dashed line). FIG. 3 illustrates the DC responsivity of SiC/AlN/AlₓGa₍₁₋ₓ₎N nip photodiode at zero, 5, 10, 15, 20, 22, 24, 25, 30, 35 and 40 volts reverse bias.

FIG. 4 is a band diagram illustrating the principles of a preferred embodiment of the present invention.

FIG. 5 illustrates the measured modulated photo response of a photodetector with varying reverse bias voltage showing an in-phase component and a quadrature component (associated with a time delay). FIG. 5 illustrates the modulated responsivity of SiC/AlN/AlₓGa₍₁₋ₓ₎N nip photodiode at zero, 10, and 30 volts reverse bias.

FIG. 6 is a schematic illustration of a crystal structure showing which the growth direction and the polarization vector for Group II and III polar (part (a)) and Group V and VI polar (part (b).

FIG. 7 is a schematic illustration of a crystal structure showing the projection of the magnitude of the polarization vector on the growth direction when the polarization vector and the growth direction are in different directions.

FIG. 8A is a schematic illustration depicting the scalar projection S in relation to the growth direction and Polarization vector P.

FIG. 8B is a schematic generalized illustration of the portions of the embodiments of FIGS. 1A and 2A which have a determinative polarization component to enable the creation of the electrostatic potential barrier formed of Group III- or Group II-polar materials and/or SiC. The left side of FIG. 8B is directed preferred embodiments in which the p-type layer is grown closest to the substrate. The right side of FIG. 8B is directed preferred embodiments in which the n-type layer is grown closest to the substrate.

FIG. 8C is a schematic generalized illustration of the portions of the embodiments of FIGS. 1A and 2A which have a determinative polarization component to enable the creation of the electrostatic potential barrier formed of Group V- or Group VI-polar materials and/or SiC. The left side of FIG. 8C is directed preferred embodiments in which the p-type layer is grown closest to the substrate. The right side of FIG. 8C is directed preferred embodiments in which the n-type layer is grown closest to the substrate.

FIG. 9 is a schematic illustration of an alternate preferred embodiment of the present invention correlating to the generalized illustration of the right side of FIG. 8B.

FIG. 10A is a schematic illustration of an alternate preferred embodiment of the present invention correlating to the generalized illustration of the left side of FIG. 8C.

FIG. 10B is a schematic illustration of an alternate preferred embodiment of the present invention correlating to the generalized illustration of the right side of FIG. 8C.

FIG. 11 is a schematic illustration of a preferred embodiment of the present invention consisting of an n-n⁻-p-SiC photodiode. At the reverse bias operating point, the illuminated n-layer is substantially depleted so that deep ultraviolet photons are substantially absorbed within the depletion region so that concomitant photogenerated carriers are collected more efficiently by drift.

FIG. 12 illustrates the measured reversed bias voltage characteristics of the preferred embodiment of FIG. 11.

FIG. 13 is a graphical illustration of the measured photoresponse of the embodiment of FIG. 11 with increasing reverse bias. The inset of FIG. 13 (upper right) illustrates the measured responsivity between 260-380 nm with increasing bias.

FIG. 14 is a graphical illustration obtained by calculating the expected unity-gain photo-response from an n-i-p SiC diode having a 35 nm thick illuminated n-doped region with increasing depletion of this layer.

FIG. 15 graphically illustrates a calculated gain in a SiC p-i-n and n-i-p diode as a function of photon wavelength at constant reverse bias where p-i-n refers to illumination of p-layer and n-i-p refers to illumination of n-layer.

FIG. 16 illustrates the calculated responsivity in a deep ultraviolet avalanche photodetector similar to the preferred embodiment of FIG. 11 with increasing reverse bias.

FIG. 17 illustrates the Electric Field distribution in a deep ultraviolet avalanche photodetector similar to the preferred embodiment of FIG. 11. The depth for full absorption of representative DUV photons to be detected within the n-i-p structure is shown by the shaded region.

FIG. 18 is an illustration of an alternate preferred embodiment comprising a transparent n-type doped AlGaN layer operatively connected to an n-n⁻-p-SiC diode of the present invention.

FIG. 19 is an illustration of an alternate preferred embodiment comprising a p-type layer adjacent to the substrate showing the neutral and quasi-neutral regions within the illuminated n-type layer.

FIG. 20 is an illustration of an alternate preferred embodiment comprising an n-type layer adjacent to the substrate showing the neutral and quasi-neutral regions within the illuminated p-type layer.

FIG. 21 is a measured doping profile for a preferred embodiment comprising an illuminated n-type layer with graded or varying Nitrogen doping with layer thickness.

FIG. 22 is an illustration of an alternate preferred embodiment comprising a p-n⁻-N⁺ photodiode illuminated through the transparent N⁺ window suitable for forming an Ohmic contact and showing the absorption region for the photons of the predetermined energy range.

FIG. 23 is an illustration of an alternate preferred embodiment comprising a n-p⁻-P+ photodiode illuminated through the transparent P⁺ window suitable for forming an Ohmic contact and showing the absorption region for the photons of the predetermined energy range.

FIG. 24 is an illustration of an alternate preferred embodiment n-AlGaN/n-SiC/p-SiC photodiode employing an n-AlGaN transparent window layer

FIG. 25 is a plot of the measured photoresponse for the fabricated n-AlGaN/n-SiC/p-SiC photodiode demonstrating enhanced deep ultraviolet response over a homogenous SiC p-i-n diode employing an illuminated recessed window.

FIG. 26 is a schematic diagram depicting the absorption depth, effective diffusion length and the depletion width.

A more complete appreciation of the invention will be readily obtained by reference to the following Description of the Preferred Embodiments and the accompanying drawings in which like numerals in different figures represent the same structures or elements. The representations in each of the figures are diagrammatic and no attempt is made to indicate actual scales or precise ratios. Proportional relationships are shown as approximates.

### DETAILED DESCRIPTION OF THE PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention. Rather, these embodiments are provided so that this disclosure will be thorough and complete, and will fully convey the scope of the invention to those skilled in the art. In the drawings, the dimensions of objects and regions may be exaggerated for clarity. Like numbers refer to like elements throughout. As used herein the term “and/or” includes any and all combinations of one or more of the associated listed items.

The terminology used herein is for the purpose of describing particular embodiments only and is not intended to limit the full scope of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various ranges, elements, components, regions, layers and/or sections, these elements, components, regions, layers and/or sections should not be limited by these terms. For example, when referring first and second ranges, these terms are only used to distinguish one range from another range. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. Furthermore, the term “outer” may be used to refer to a surface and/or layer that is farthest away from a substrate.

This description and the accompanying drawings that illustrate inventive aspects and embodiments should not be taken as limiting—the claims define the protected invention. Various changes may be made without departing from the spirit and scope of this description and the claims. In some instances, well-known structures and techniques have not been shown or described in detail in order not to obscure the invention. Additionally, the drawings are not to scale. Relative sizes of components are for illustrative purposes only and do not reflect the actual sizes that may occur in any actual embodiment of the invention. Like numbers in two or more figures represent the same or similar elements. Elements and their associated aspects that are described in detail with reference to one embodiment may, whenever practical, be included in other embodiments in which they are not specifically shown or described. For example, if an element is described in detail with reference to one embodiment and is not described with reference to a second embodiment, the element may nevertheless be claimed as included in the second embodiment.

Embodiments of the present invention are described herein with reference to cross-section illustrations that are schematic illustrations of idealized embodiments of the present invention. As such, variations from the shapes of the elements in the illustrations are to be expected. Thus, embodiments of the present invention should not be construed as limited to the particular shapes of regions illustrated herein but are to include deviations in shapes. Thus, the layers or regions illustrated in the figures are schematic in nature and their shapes are not intended to illustrate the precise shape of a layer or region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the terminology n+ layer means an n-type layer with increased doping concentration, p+ layer means a p-type layer with increased doping concentration, n⁻-layer means a n-type with sufficiently low doping so that it is mostly depleted at zero bias, p⁻-layer has sufficiently low doping so that it is mostly depleted at zero bias

As used herein, the terminology N-layer refers to a layer having n-type doping and is transparent at the wavelength of interest for detection and the terminology P-layer refers to a layer having p-type doping and is transparent at the wavelength of interest for detection

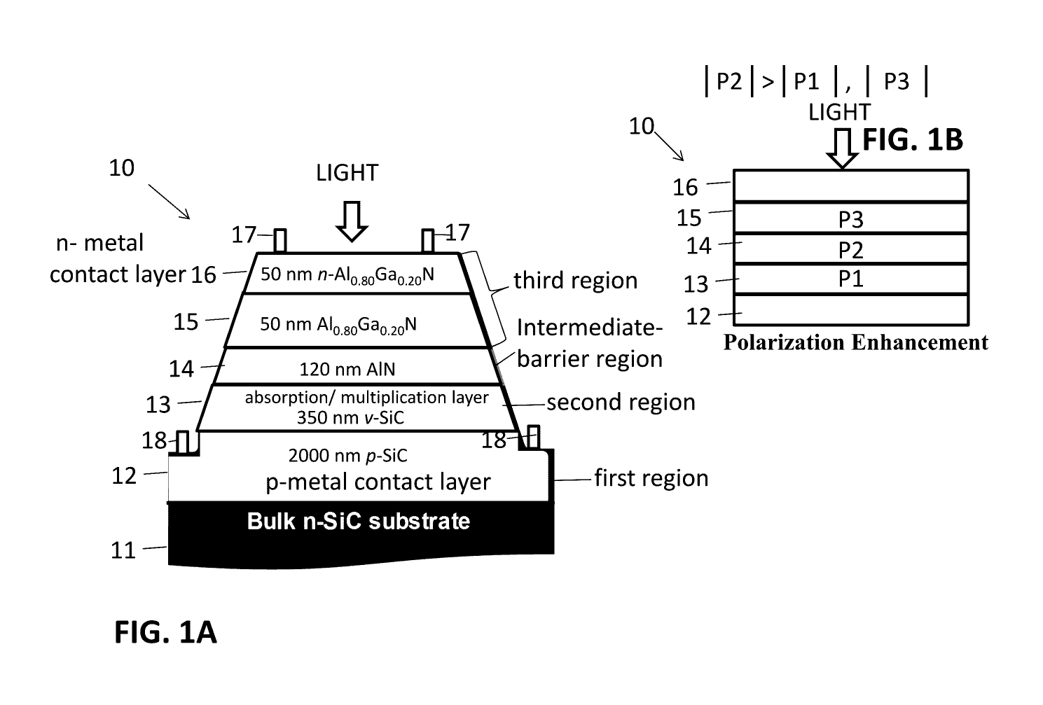

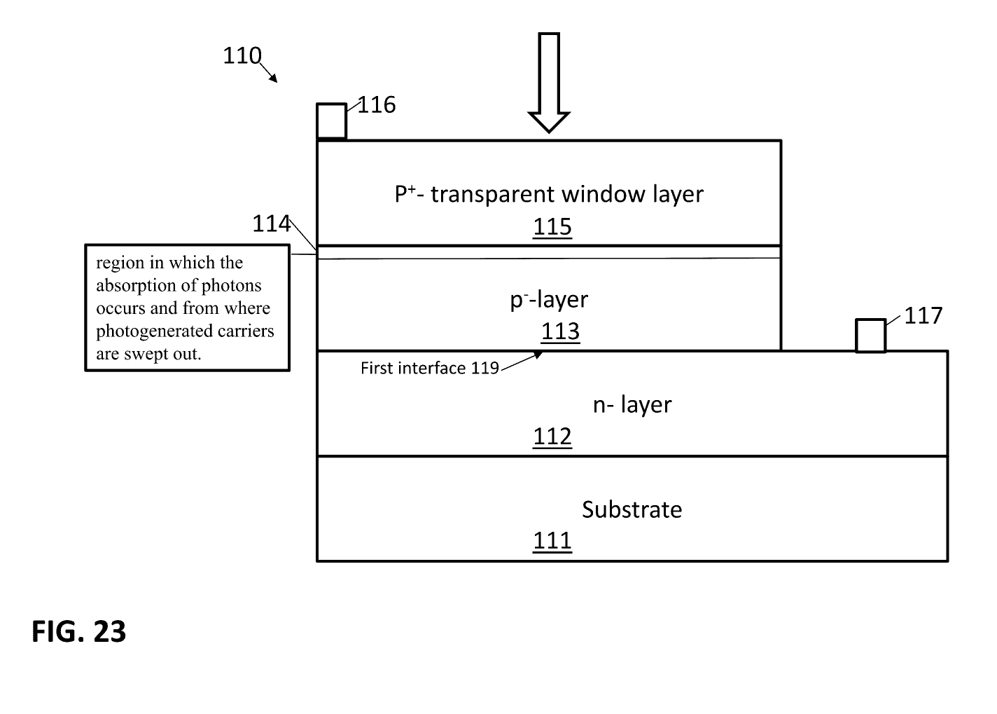

As described in U.S. patent application Ser. No. 14/285,964, hereinafter the '964 application) the preferred embodiment 10 of FIG. 1 may be, for example, a III-Nitride/SiC nip structure comprising a p-type semiconductor metal contact region or layer 12, which may be, for example, a 2 μm thick p-SiC layer doped 2×10¹⁹ cm⁻³, an absorption/multiplication region or layer 13, which may be, for example, a 350 nm thick n⁻-SiC layer lightly doped n-type 5×10¹⁵ cm⁻³, a transparent barrier region or layer 14, which may be, for example, a 120 nm thick AIN layer, a transparent window layer or region 15, which may be, for example, a 50 nm thick Al_{0.80}Ga_{0.20}N layer 15, and a region 16 suitable for forming an n-metal contact, which may be, for example, a 50 nm thick n+-Al_{0.80}Ga_{0.20}N layer. The thickness of barrier region or layer 14 may be as thin as 5 nm. The region or layer 15 is predominantly transparent to photons of interest for conversion in that these photons are generally not converted to electrons and holes in region or layer 15. The SiC epitaxial layers or regions may be grown on n-type Si-face 4H—SiC substrate 11. The Ill-polar AlₓGa₍₁₋ₓ₎N epitaxial layers or regions may be heteroepitaxially grown by plasma assisted molecular beam epitaxy at 780° C. directly upon the SiC epitaxial layers or regions. The two AlₓGa₍₁₋ₓ₎N layers or regions 15 and 16 may be combined into a single layer and may be fully strained to the AIN region 14, which is relaxed, as determined by high resolution x-ray diffraction. Epilayers were fabricated into 250 μm diameter, circular mesas with seven degree beveled sidewalls. The n-AlₓGa₍₁₋ₓ₎N Ohmic contact 17 comprises of a stack comprising Ti 10 nm/Al 100 nm/Ni 30 nm/Au 50 nm metallization scheme while the p-SiC Ohmic contact 18 consists of Ni 25 nm/Ti 35 nm/Al 100 nm/Ni 80 nm. The contacts 17 and 18 are similar to element number 7 in the U.S. Pat. No. 8,269,223, FIG. 23, herein incorporated by reference. The selection of metals for the contact layer depend upon metal work-function, adhesion, as well as impurity diffusion considerations. There are a number of Ohmic contacts schemes to n-AlGaN and p-SiC reported in the literature. The stacks that may be used are commonly employed. The constraint is that the contacts make a low resistance Ohmic contact; in contrast to a Schottky contact.

As described in the '964 application, the semiconductor absorption/multiplication region 13 (which may be designated herein as a second region), barrier region or layer 14 (which may be designated herein as an intermediate region) and the third region 15 each have a total polarization P1, P2 and P3, respectively. In accordance with the principles of the present invention, the magnitude of the total polarization of the barrier region 14 having a polarization magnitude P2 (defined in terms of absolute value) that is greater than either of the magnitudes of the total polarizations of the absorption/multiplication region 13, which has a total polarization of P1, or the transparent region 15, which has a total polarization of P3. This results in interface charge densities due to the discontinuity in polarization at the heterointerfaces between regions 13, 14 and 15 that enable a large electrostatic potential barrier and therefore a large electric field across region 14 that suppresses the collection of photogenerated carriers excited to the lower energy band gaps of region 13. As a result, this structure eliminates or reduces the requirement for an optical filter for tuning the bandwidth of the photodetector near the lower energy band gaps of absorption/multiplication region.

As described in the '964 application, it is important to note that the dipole strength and energy barrier presented for carrier transport by the barrier layer 14 is dependent on the net total charge at the heterointerfaces between the barrier layer 14 and the absorption multiplication layer 13 as well as interface between the barrier layer 14 and the n-metal contact layer 15 or 16, and the doping of these layers may be used to further modify the dipole strength and energy barrier. Specifically, the introduction of ionized acceptor impurities at the heterointerface between the barrier layer 14 and the absorption multiplication layer 13 or ionized donor impurities at the heterointerface between the barrier layer 14 and the n-metal contact layer 15 or 16 may be used to reduce the net total charge at either of these interfaces and therefore reduce the dipole strength and energy barrier. Conversely, the introduction of ionized donor impurities at the heterointerface between the barrier layer 14 and the absorption multiplication layer 13 or ionized acceptor impurities at the heterointerface between the barrier layer 14 and the n-metal contact layer 15 or 16 may be used to increase the net total charge at either of these interfaces and therefore increase the dipole strength and electrostatic potential barrier. By adjusting the charge, the height (in terms of energy needed to surmount it) of the electrostatic potential barrier may be adjusted.

By using a transparent layer or region 15 comprising AlₓGa₁₋ₓN in conjunction with the preferred embodiment 10 shown in FIG. 1A, the short wavelength cutoff of AlₓGa₁₋ₓN can be tuned from 365 to 200 nm.

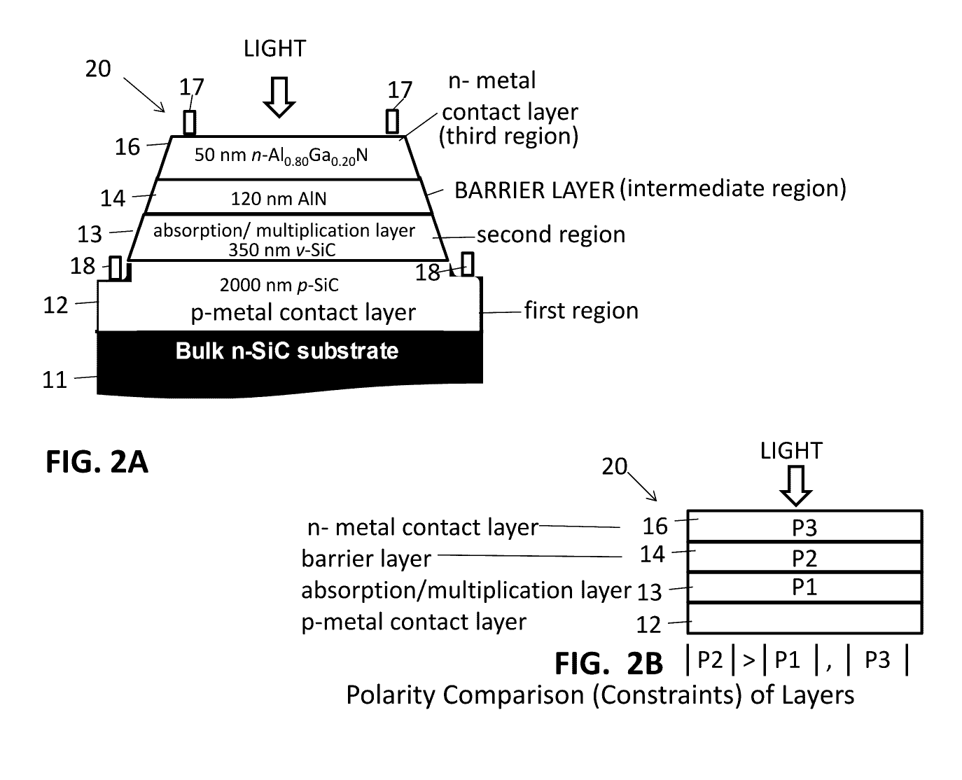

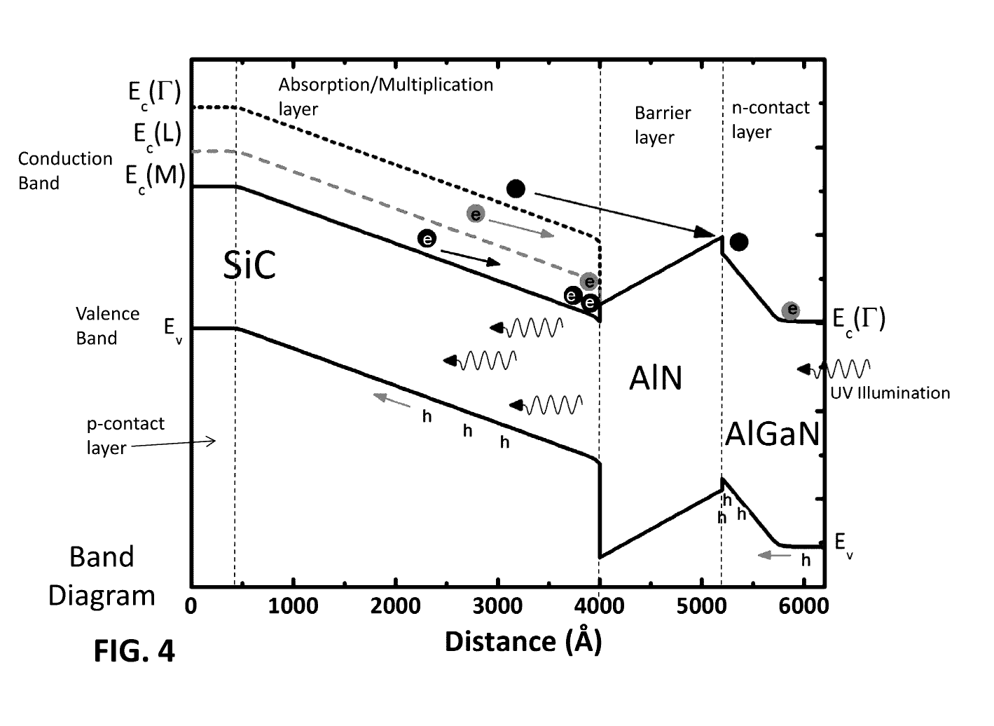

As described in the '964 application, an alternative preferred embodiment assembly 20 is illustrated in FIG. 2A. The preferred embodiment 20 comprises a p-metal contact layer or region 12 which may be positioned or formed on a substrate 11, such as a bulk SiC substrate. The absorption/multiplication region or layer 13 is formed on the p-metal contact layer 12 as shown in FIG. 2A. Barrier layer or region 14 is formed on region 13 and n-metal contact layer or region 16 is formed on the barrier region 14. As illustrated in FIG. 2B, the magnitude of the total polarization P2 of the barrier region 14 (which may be denoted herein as the intermediate region) is greater than the magnitude of the polarization of either of the regions 13 (P1) (which may be denoted herein as the second region) or 16 (P3) (which may be denoted as the third region). The interface charge densities that arise due to the discontinuity in polarization at the interfaces between regions 13 and 16 with respect to barrier region 14 enable a large electrostatic potential barrier and therefore a large electric field across barrier region 14 that suppresses the collection of photogenerated carriers excited to the lower energy band gaps of absorption/multiplication region 13, as depicted in general by the band diagram shown in FIG. 4.

As described in the '964 application, material selection for the regions 13, 14 and 16 may include any semiconductor materials for which the conditions |P2|>|P3″ and |P1| are satisfied. That is, the magnitude of the polarization of the barrier region 14 is greater than the magnitude of the polarization of the n-metal contact layer 16 and the absorption/multiplication region 13. For example, the regions could be alloys of AlₓGa₁₋ₓN where different amounts of aluminum are used to regulate the magnitude of polarization. Other examples are magnesium zinc oxide, aluminum gallium arsenide, indium gallium arsenide, and indium gallium nitride. A further example is where the P1 material is chosen as silicon and the P2 and P3 regions aluminum gallium nitride. The electrostatic potential energy barrier in barrier region 14 is significantly enhanced by the dipole formed by the fixed interface polarization charge induced by the difference in polarization between the barrier region and the absorption/multiplication and n-contact regions. As is known, without a barrier, holes migrate to the p contact and electrons migrate to the n contact. The barrier region 14, in FIGS. 1A, 1B, 2A and 2B prevents hole transport and collection from the AlₓGa₁₋ₓN layer (15 in FIG. 1, 16 in FIG. 2). High energy photogenerated electrons in the SiC absorption/multiplication region (13) can traverse the barrier region and be collected in the n-metal contact region 16 in FIG. 1 or 2. Lower energy photogenerated electrons in SiC absorption/multiplication region 13 cannot traverse the barrier layer, so those carriers are not collected. As a result, long wavelength photoresponse is suppressed without using an optical filter.

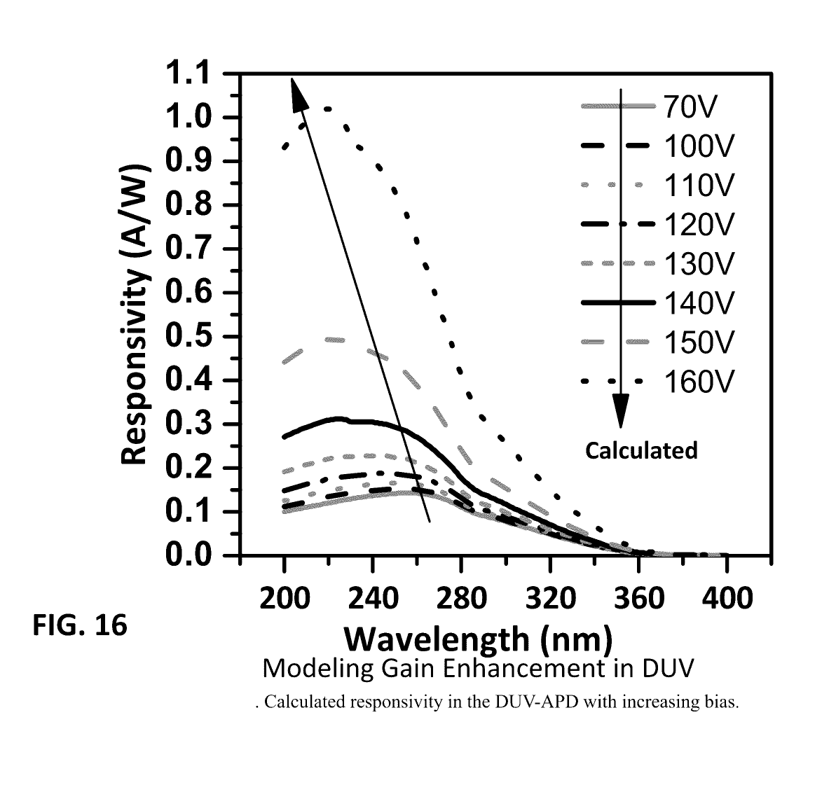

As described in the '964 application, the employment of polarization induced charge densities arising from the difference in polarization between the barrier layer 14 and the surrounding regions results in significant suppression of long wavelength response in the device without requiring an optical filter. As shown in the band diagram of FIG. 4, the barrier region of a Group-III Nitride material, which in this case is AlN, creates a barrier for the transport of electrons excited to the L and M conduction bands of the absorption multiplication region 13, which in this case is SiC, (shown to the left of FIG. 4). When referring to the polarization of the regions 13, 14, and 15, the polarizations are compared using the Scalar Projections S₁, S₂, S₃, which are defined as the absolute values of the magnitudes of the polarizations P1, P2, P3 times the cosine of the angle between the direction of the polarizations and the growth direction. In FIG. 4, a positive polarization charge is formed at the interface of the material where S₂<S₁ (i.e., AlN/SiC interface), while a negative polarization charge is formed at the interface of the material where S₂<S₃ (i.e., AlN/AlₓGa₁₋ₓN interface). Note that each of S₁, S₂ and S₃ are negative. The barrier region 14, in an AlₓGa₁₋ₓN/AlN/SiC photodetector constructed in accordance with the principles of the present invention, enables a solar-blind detector structure that can leverage the low dark current, and high gain of SiC while suppressing its long wavelength response without using an optical filter. In addition, the barrier height presented by region 14 is adjustable by varying the bias voltage, as increasing the reverse bias voltage results in lowering the barrier. The long wavelength photoresponse is suppressed through the formation of an energy barrier that prevents the collection of carriers generated by lower energy photons that are absorbed in the detector. This energy barrier is principally due to the dipole formed across the barrier region that arises from polarization interface charge densities induced by the difference in total polarization between the barrier region and the surrounding regions in the structure; including on one side larger magnitude spontaneous polarization of AlN (barrier region 14) over SiC (absorption-multiplication region 13), and, on the opposite side, over AlₓGa₁₋ₓN region 15 in FIGS. 1A and 16 in FIG. 2A. The barrier height increases with barrier region layer 14 thickness in association with the first and second interface charges and can be significantly larger than band offsets. With respect to the embodiment of FIG. 1A, the barrier region 14 blocks collection of holes photogenerated in AlₓGa₁₋ₓN contact window region 15. Likewise, with respect to the embodiment of FIG. 2A, the barrier 14 blocks collection of holes generated in AlₓGa₁₋ₓN metal contact region 16. As shown in the band diagram of FIG. 4, the barrier permits transport of electrons generated in an upper conduction band valley of SiC (see E_{c}(Γ)), but blocks transport from lower valleys (see E_{c}(M) and E_{c}(L)). Increasing reverse bias reduces the barrier height to permit collection of some electrons generated in lower conduction bands, thereby increasing long wavelength response.

As described in the '964 application, the embodiment of FIG. 1A (incorporating a transparent window 15) is preferred in that, with reference to FIG. 4, the distance over which the potential is dropped within the n-contact region can be modified by adjusting the doping profile within the extended n-contact region (or transparent region 15). In the embodiment of FIG. 1, the doping on the transparent region 15 adjacent to the AlN barrier region 14 has been reduced. Reduction of the doping in the region adjacent to the barrier region 14 is represented by FIG. 4. If the doping was high throughout the n-contact layer, as in the case of FIG. 2A, a much sharper drop in potential would occur in this layer; leading to a larger electric field that may be desirable in some instances.

As described in the '964 application, the preferred embodiments of the present invention shown in FIGS. 1A, 1B, 2A and 2B comprise a heterogeneous n-III-Nitride/i-p-SiC structure operable to extend the deep ultraviolet (DUV) response of SiC below 260 nm, while suppressing the long wavelength response. Since the direct bandgap of aluminum gallium nitride (AlₓGₐ₍₁₋ₓ₎N) can be engineered from 3.4 eV to 6.1 eV depending on the AlN to GaN mole fraction, these alloys are employed as UV transparent, n-type contact windows (for example, the transparent windows 15 and 16 in FIG. 1A) to increase the collection of carriers created by absorption of high energy photons in the high electric field depletion region of the nip structure. As described in the following, photo-generated carriers in the AlₓGₐ₍₁₋ₓ₎N windows do not contribute to photoresponse and can therefore be used to adjust the high energy cutoff wavelength of this device.

As described in the '964 application, in order to suppress the long wavelength response of SiC between 260 nm and 380 nm, the preferred embodiments 10 and 20 of FIGS. 1A and 2A, respectively, utilize polarization charge densities induced at the interfaces using a barrier region 14 to create a large barrier to transport and allow only electrons excited by high energy photons to higher energy bands within the SiC region to be collected. Further utilizing a transparent window in the embodiment 10 of FIG. 1A, this transparent window 15 and electron filter (barrier 14) facilitate the fabrication of high responsivity, narrow bandwidth detectors in which the spectral response can be adjusted though the window and barrier properties.

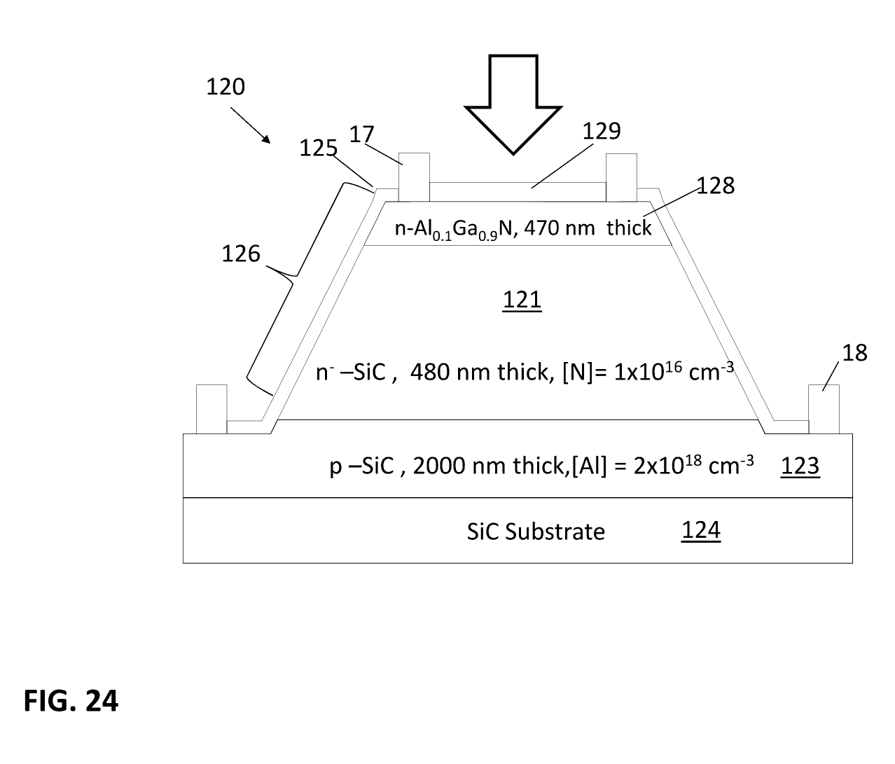

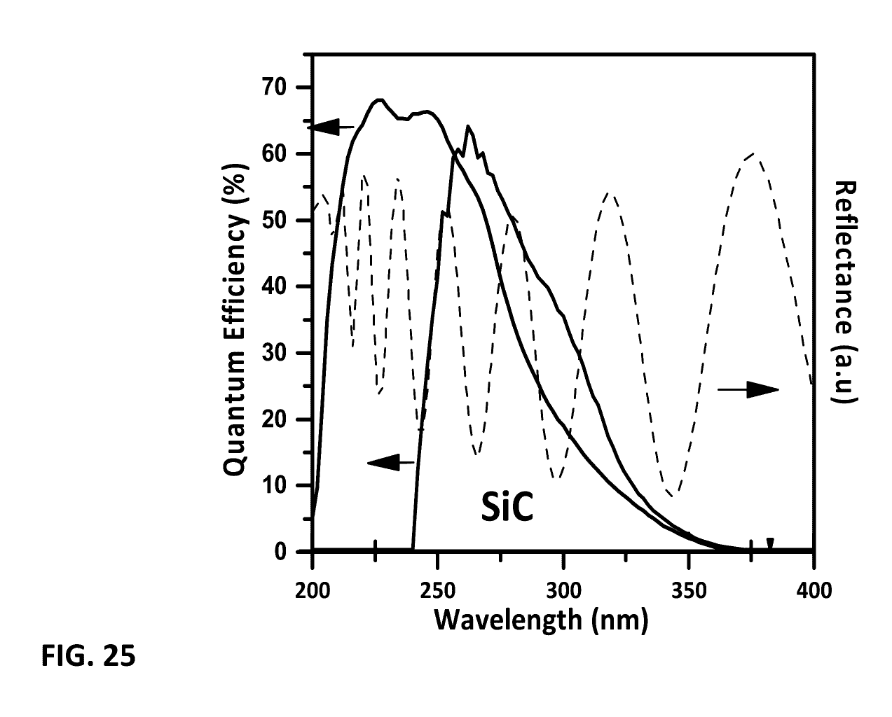

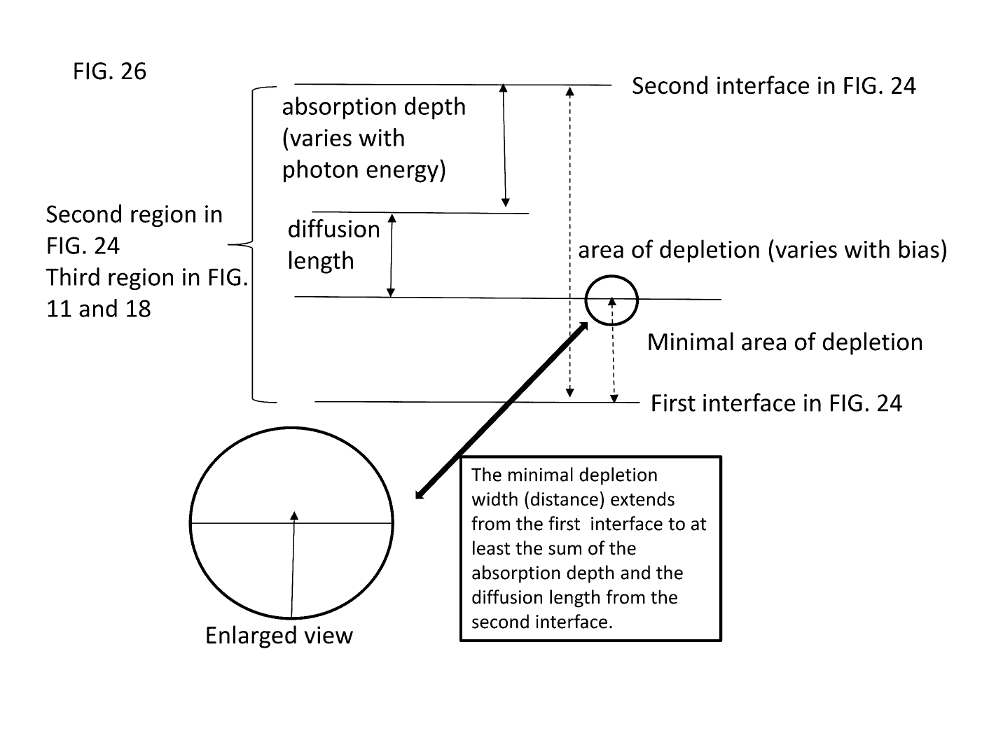

As described in the '964 application, note that the barrier region 14 functions in a manner different from the interface charge control layer disclosed in U.S. Pat. No. 8,269,223 ('223 patent). As shown in FIG. 24 of the '223 patent, an AlₓGₐ₍₁₋ₓ₎N interface charge control layer (ICCL) 5F operates to improve the transport of holes generated in the GaN:UID layer into the 480 nm SiC:UID layer. Note further that in the '223 patent, the thickness of interface charge control layer is much thinner than the thickness of barrier region 14 of the embodiments shown in FIGS. 1A and 2A herein. The reduced thickness in the '223 patent results in conduction and valence band bending associated with the formation of a dipole over a very short distance. As a result, this facilitates the transfer of holes from the GaN absorption region to the SiC multiplication region in the heterogeneous GaN—SiC separate absorption and multiplication (SAM) APD and was called a nitride interface charge control layer (ICCL) (see '223 patent for details). The coinventors have now theoretically found that this only occurs if the thickness of the AlN region is less than 5 nm; at thicknesses greater than that the barrier created by the dipole will prevent photogenerated holes in the GaN:UID from being collected in the SiC:UID layer. In comparison to U.S. Pat. No. 8,269,223, the thickness of AlN is about one percent of the thickness of the barrier region 14. Thickness reduction results in band bending over a very short distance (˜1 nm), that facilitates tunneling of holes from the GaN absorption region to the SiC multiplication region. In the GaN—SiC structure disclosed in the '223 patent, the photoresponse is primarily associated with hole injection to the p-contact layer. In preferred embodiments of FIGS. 1A and 2A, the AlN barrier region 14 is sufficiently thick so that the hole transport from the n-contact layer 16 or transparent AlₓGa₁₋ₓN region 15 to the absorption/multiplication region 13 is blocked. However, the barrier in the conduction band allows the transport of high energy photogenerated electrons in the SiC region to cross into the III-Nitride region while simultaneously suppressing the collection of electrons generated by lower energy photons in SiC associated with wavelengths between 260-380 nm.

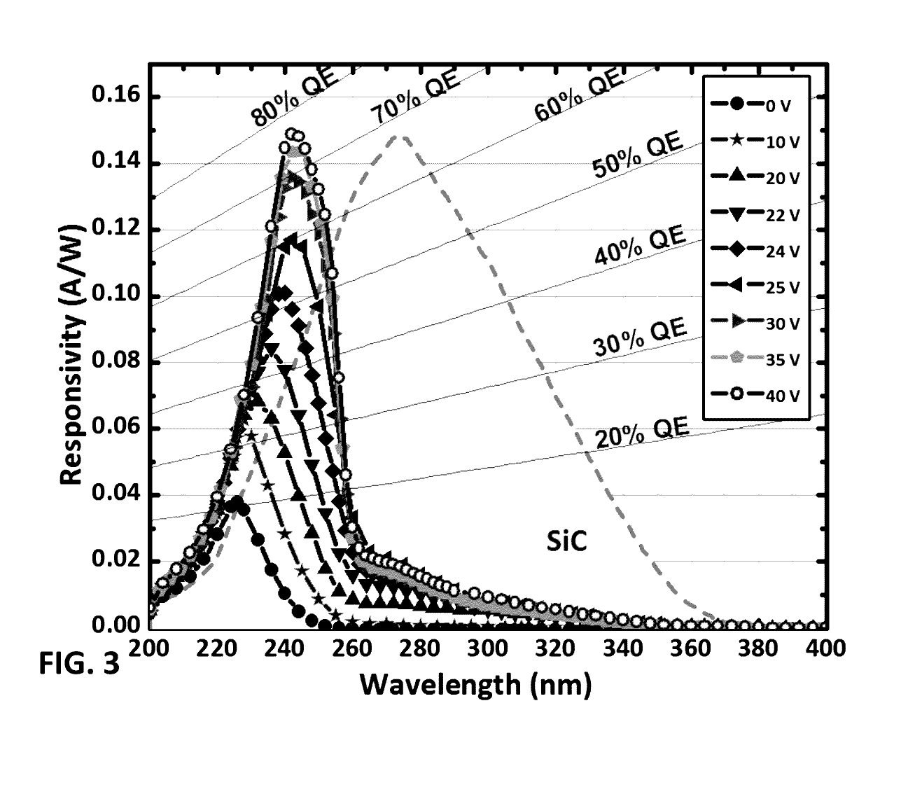

As described in the '964 application, FIG. 3 illustrates the effect of the barrier region 14 of the preferred embodiments of FIGS. 1A and 2A on the collection of photogenerated electrons in SiC between 260-380 nm. A similar result is expected for a barrier region 14 composed of InAlGaN compositions having greater magnitude total polarization (represented by /P2/ in FIGS. 1B and 2B) than the absorption/multiplication region 13 (represented by /P1/ in FIGS. 1A and 2A) and transparent region 15 (of FIG. 1A) or n-metal contact region 16 of FIG. 2A (represented by /P3/). Specifically, FIG. 3 illustrates the measured DC responsivity of the SiC/AIN/AlₓGa₍₁₋ₓ₎N preferred embodiment detector at varying reverse bias (closed figures). For comparison, the DC photoresponse of a homogeneous SiC pin photodiode under unity gain operation is also provided in FIG. 3 (dashed line). At zero bias the DC responsivity is characterized by a single peak around 226 nm with a quantum efficiency (QE) of 20% that is comparable to that of the SiC pin diode. However, the DC response exhibits a strong reverse bias voltage dependence, with peak response increasing and red-shifting with increasing bias. A peak QE of approximately 76% at 242 nm is observed for these devices at 40V that is significantly higher than what is observed for conventional homogeneous SiC pin photodiodes. It is also important to note that the DC response of the SiC/AlN/AlₓGa₍₁₋ₓ₎N diodes has a sharp high pass cutoff at approximately 260 nm. The barrier region 14 allows the transport of high energy photogenerated electrons in the SiC region to cross into the III-Nitride region while simultaneously suppressing the collection of electrons generated by lower energy photons in SiC associated with wavelengths between 260-380 nm. The thinnest effective barrier region 14 ranges from approximately 5 nm.

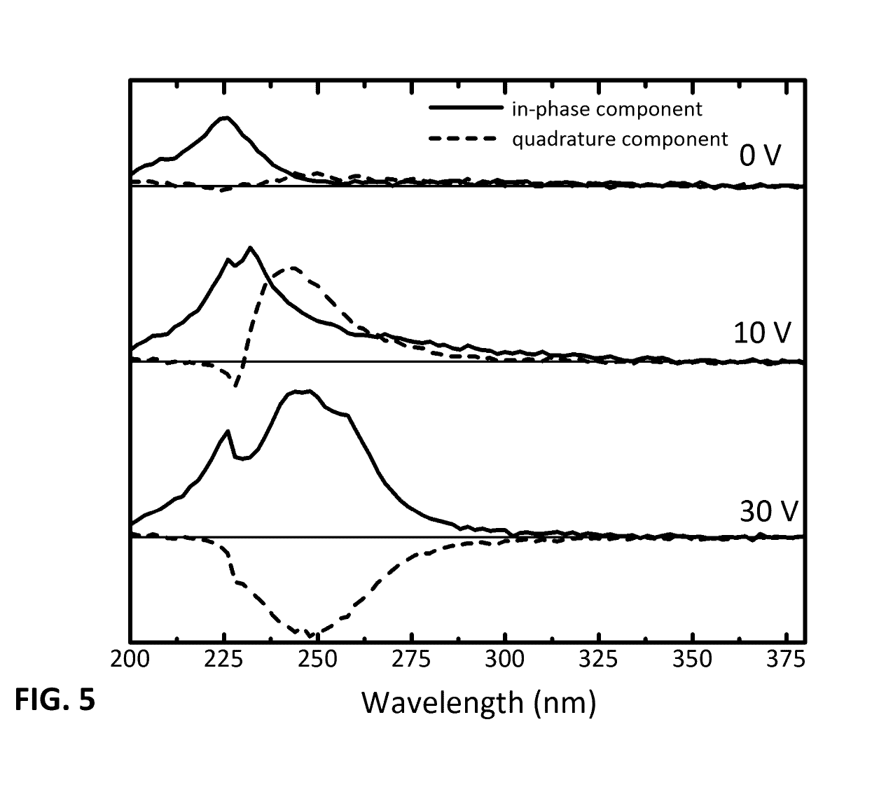

As described in the '964 application, FIG. 5 shows the measured modulated photoresponse of a typical detector with varying reverse bias voltage. This figure includes the in-phase, or x-component, and the quadrature, or y-component, signals. Consistent with DC measurements, the modulated response also exhibits a single peak at 226 nm at zero bias. The majority of this signal is in the in-phase component with negligible quadrature contribution. Increasing reverse bias voltage results in the increase in the long wavelength contribution; however, unlike the DC measurement, this contribution centered around 242 nm appears distinct from the 226 nm peak. At all reverse bias voltages, the signal below 226 nm has minimal phase delay as indicated by the almost zero quadrature component. The quadrature component appears primarily positive for low bias voltages and turns negative for large bias voltages. It should be noted that in both bias conditions there is a distinct bias dependent, negative quadrature component at 228 nm. Although not as sharp as in the DC measurement, the modulated response also exhibits the long wavelength cutoff at approximately 260 nm.

As described in the '964 application, the origins of the observed spectral response can be understood by considering the influence of the AIN barrier region 14. FIG. 4 shows an illustration of the band alignment between the direct E_{c}(Γ) and indirect (E_{c}(L), E_{c}(M)) conduction band valleys of 4H—SiC and the direct Γ—valley of the III-Nitride region at zero bias under UV illumination. For the solid lines shown in the central portion of FIG. 4, this illustrates the case where lowest conduction band of SiC is in alignment with AlN. The transition energy between the Γ-M, Γ-L and Γ-Γ valleys of SiC was assumed to be 3.25 eV, 4 eV, and 5 eV, respectively, as provided by the Ioffe Physico-Technical Institute. It should be noted there is some uncertainty in these values, especially for the Γ-Γ transition which may lie between 5-6 eV.

As described in the '964 application, at zero bias, there is a large field generated in the AlN region as a result of the positive polarization induced interface charge at the SiC/AlN interface and negative polarization induced interface charge at the AlN/AlₓGa₍₁₋ₓ₎N interface. This field, combined with the difference in bandgap, creates a large interface barrier which impedes the injection of holes from AlₓGa₍₁₋ₓ₎N to SiC and electrons from SiC to AlₓGa₍₁₋ₓ₎N, depending upon the energy of the conduction band valley into which the electrons are photoexcited. As shown in FIG. 4, under optical excitation, photogenerated holes in AlₓGa₍₁₋ₓ₎N accumulate at the AlN/AlₓGa₍₁₋ₓ₎N interface forming a 2 dimensional hole gas (2DHG) and electrons in the lower, M and L valleys of SiC accumulate at the SiC/AlN interface forming a 2 dimensional electron gas (2DEG). These accumulated charges partially cancel the polarization charge at each interface and reduce the overall barrier height. Photogenerated holes in the AlₓGa₍₁₋ₓ₎N region are still unable to overcome this barrier and therefore no response from AlₓGa₍₁₋ₓ₎N is observed, as evidenced by the high energy cutoff in the photoresponse shown in FIGS. 3 and 4 that corresponds to absorption in this layer. Likewise, there is approximately a 2 eV barrier between the M valley of 4H—SiC and AlN which impedes electron injection across the interface leading to a suppressed long wavelength response from SiC. On the other hand, this barrier has a minimal impact on the transport of electrons excited to the Γ valley across the interface and therefore these carriers are collected as illustrated by the lightly shaded electrons in FIG. 4. The presence of the 226 nm peak in both the DC and modulated measurements at zero bias is therefore likely due to the direct collection of carriers excited to the Γ valley. This conclusion is supported by the lack of phase delay in the modulated photoresponse at wavelengths shorter than 226 nm, which indicates that the signal experiences no time delay associated with the accumulation of carriers at the interface. Due to the large electric field in the SiC region 13, it is expected that the carriers in the Γ valley are hot when they reach the barrier and are able to overcome it without difficulty. It is interesting to note that the reported hot electron energy relaxation time in 4H—SiC is about 2.5 psec. Using a saturation velocity of 2×10⁷ cm/sec for electrons in SiC, the calculated average time for an electron to reach the SiC/AlN interface is about 1.7 psec. Considering the strong absorption due to the Γ-Γ transition, most carriers excited at 226 nm are likely generated within 1/α cm of the SiC/AlN interface and therefore the average time may be even shorter. However, since the QE measured in this work at 226 nm is only 20%, considerably lower than expected, the hot electron energy relaxation time in the Γ valley might be even shorter than 2.5 psec.

As described in the '964 application, as indicated in FIG. 3, increasing the reverse bias voltage increases (decreases) the electric field in the SiC (AIN) region; thus lowering the barrier for carrier injection across the interface. The field is increased in the SiC region and decreased in the AlN region. Although reduced, the barrier continues to impede photo-generated holes in the AlₓGa₍₁₋ₓ₎N layer. However, as indicated by the redshift (shifting to a longer wavelength) in the DC photoresponse, hot electrons in lower energy bands of SiC are able to overcome the barrier and be collected. The peak QE of 76% at 40 V is almost double that of typical SiC pin diodes, which exhibit approximately 40% QE at 242 nm under unity gain. This enhanced DUV response is not due to photoconductive gain since the operation of this device relies on the accumulation of both holes and electrons at the interface to lower the barrier. In the modulated measurement at large reverse bias voltages, the long wavelength response experiences a ˜50 degree phase delay as compared to the 226 nm peak and can be attributed to the charge-accumulation process discussed previously. Considering the spontaneous polarization charge density of 5×10⁻⁷ C/cm² and the photogenerated current density of 3×10⁻⁵ A/cm² at optical power of 100 nW and wavelength of 242 nm, the phase delay in these measurements is reasonable. The 226 nm peak exhibits no bias dependence in DC or modulated measurements indicating that this signal is due to the collection of carriers directly from the Γ valley and not from carriers that have relaxed from the Γ valley to lower energies. Collection of relaxed carriers would likely have a bias dependence based on the lowering of the barrier. The negative quadrature component at 228 nm represents the on-set of the interaction with the barrier and is due to hot electrons in the bottom of the Γ valley able to tunnel through the barrier. As a result, this signal does experience a phase delay and is bias dependent. This further indicates that the collection of electrons leading to the 242 nm peak are from the lower energy L valley. At low bias voltages, these carriers are impeded by the barrier and therefore their contribution to the photoresponse is suppressed, while at large bias voltages, these carriers are delayed as compared to the 226 nm signal due to interaction with the barrier. Although not shown here, increasing the power of the optical illumination results in a reduced phase lag of the long wavelength signal due to a faster barrier lowering process.

As described in the '964 application, for all bias voltages, the long wavelength (<260 nm) response from the collection of carriers in the M valley is strongly suppressed as shown in the DC photo-response in FIG. 3. This suppression effect is due to the same barrier that creates the bias dependent operation. At large reverse bias voltages investigated in this work, electrons in the M valley of SiC are unable to overcome the barrier at the interface. These carriers instead accumulate at the interface as described previously. The long wavelength filtering effect is slightly less effective in the chopped response due to the time required to accumulate charge at the interface. Under low reverse bias operation, the charge accumulation results in a measureable displacement current indicated by a leading phase, indicated by the positive quadrature component at 10 V. At higher reverse bias voltages (20V-30V), the barrier is lowered and fewer charges are required to form the 2DEG and 2DHG. Under these conditions, the photo-current dominates the displacement current resulting in the phase lag of the signal.

As described in the '964 application, the use of AlₓGa₍₁₋ₓ₎N alloys as a transparent n-type window increases the collection of electrons created by absorption of high energy photons in the high-field n⁻-SiC region. Peak QE of 76% at 242 nm has been measured and attributed to the minimization of the effects of surface states and absorption in heavily doped layers currently hindering homogeneous SiC devices. Utilizing the large polarization induced interface charges in these material systems to create a barrier at the interface has been demonstrated to filter the long wavelength response by prohibiting collection of carriers from the M valley of SiC. Adjusting the field in the barrier region through the difference in polarization and thickness adds further control over the long wavelength cutoff and also voltage response.

As described in the '964 application, FIG. 5 shows the measured modulated photoresponse of a photodetector with varying reverse bias voltage. FIG. 5 illustrates the modulated responsivity of SiC/AlN/AlₓGa₍₁₋ₓ₎N nip photodiode at zero, 10, and 30 volts reverse bias. In-phase component waveforms and quadrature waveforms are illustrated in FIG. 5. Illumination with chopped light was used to facilitate the measurement. The presence of a quadrature waveform component indicates a time delay associated with the measurement. At zero volts, the quadrature component is near zero throughout the wavelength range of 200 to 375 nanometers. At both 10 and 30 volts, the quadrature component is near zero in the 200-220 nm (approximate) range, showing the negligible effects of time delay presumably due to gamma (E_{c}(Γ)) valley electrons surmounting the AlN barrier layer, represented by the upper dashed line in FIG. 4. As the wavelength increases, a positive quadrature component indicates the presence of a time delay effect as the quadrature component increases with respect to 10 volts and decreases with respect to 30 volts. FIG. 5 also illustrates that as the reverse bias voltage increases, the AlN barrier decreases in effect, resulting in the wavelength range increasing as shown by the graphs representing the reverse bias voltages of 10 and 30 volts where the long wavelength cut-off in the photoresponse moves to longer wavelength from near 250 nm (in the case of zero volts) to approximately 270-300 nm.

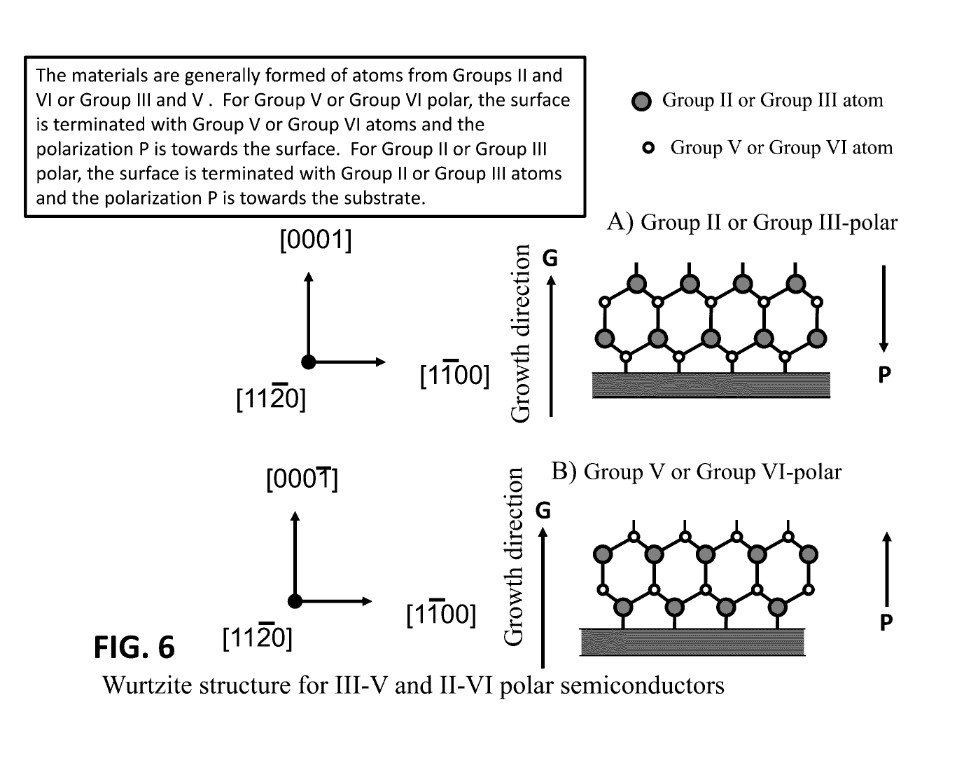

As described in the '964 application, some of the material layers forming the photodetector are generally formed of atoms from Groups II and VI or Groups III and V. In FIG. 6, the materials are referred to as being Group II or III polar or Group V or VI polar. For Group V or Group VI polar, the surface is terminated with Group V or Group VI atoms and the polarization P is towards the surface. For Group II or Group III polar, the surface is terminated with Group II or Group III atoms and the polarization P is towards the substrate. FIG. 6 part (a) is a schematic illustration of a crystal structure in which the growth direction and the polarization vector are in the opposite direction.

As described in the '964 application, FIG. 6 part (b) is a schematic illustration of a crystal structure in which the growth direction and the polarization vector are in the same direction.

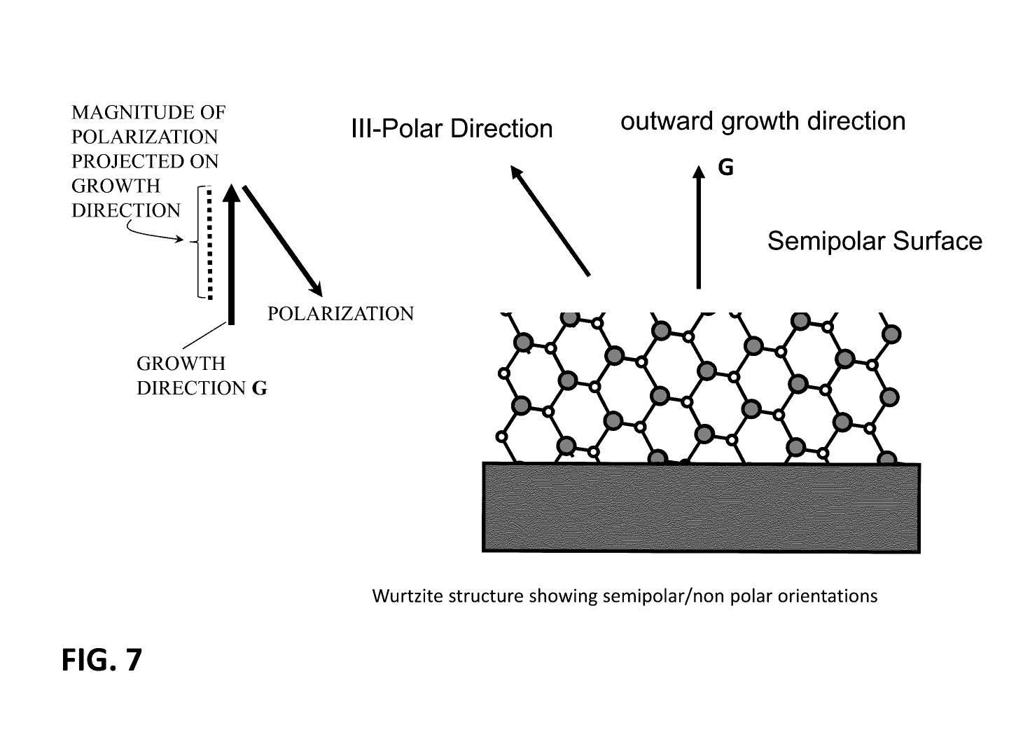

As described in the '964 application, FIG. 7 is a schematic illustration of a crystal structure showing the projection of the magnitude of the polarization vector on the growth direction when the polarization vector and the growth direction are in different directions.

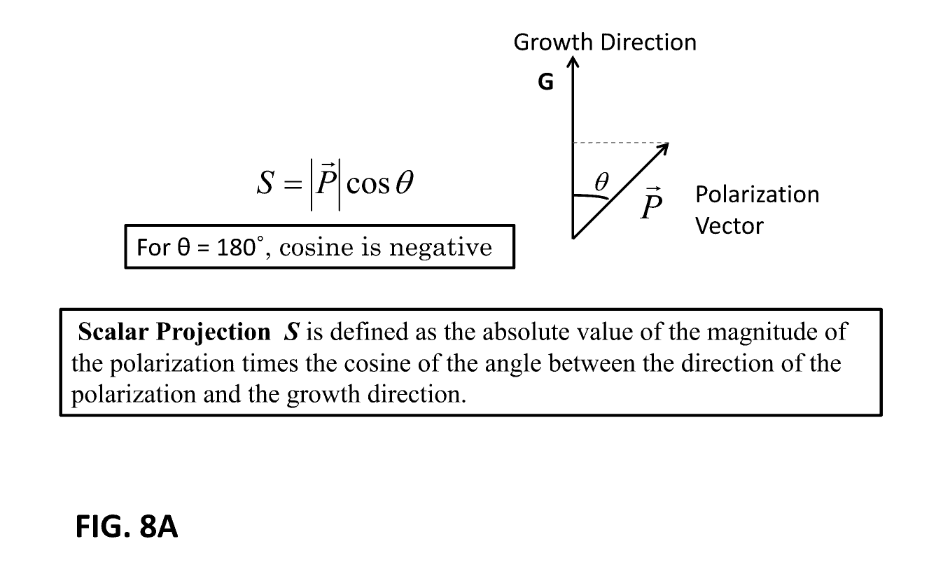

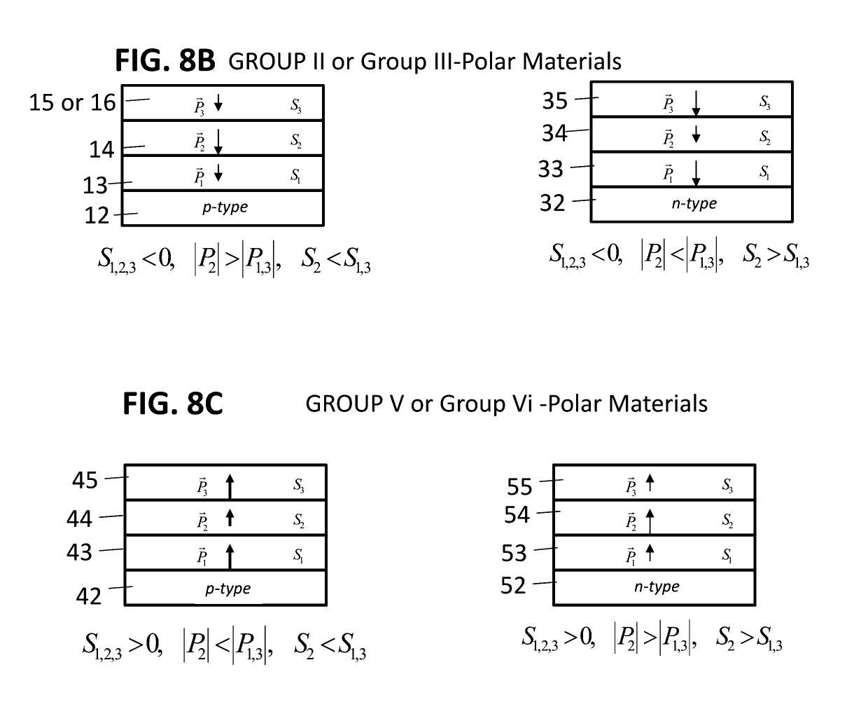

As described in the '964 application, FIG. 8A is a depiction of the definition of the scalar projection S as used in the specification and claims. The growth direction refers to the growing of the crystal lattice structure, as illustrated in FIGS. 6 and 7. The polarization vector refers to the total polarization for a particular region (or layer) as referenced above as the absolute value or magnitude of the polarization in FIGS. 1B and 2B. The projection of the polarization vector P on the vector G (designating the growth direction) can also be referred to as the scalar resolute or scalar component of P in the direction of the growth direction G, represented mathematically by:

S=|P|cos θ=P·Ĝ

where the operator (·) denotes the dot product, Ĝ is the unit vector in the direction of the Growth Vector G, |P| is the magnitude of the polarization vector P, and θ is the angle between vectors P and G. Note that the scalar projection is equal to the length or magnitude of the projection of P onto G, with a minus sign if the projection has an opposite direction with respect to G. With reference to the right side of the above equation, multiplying the scalar projection of P on G by Ĝ converts it into the foregoing projection, also referred to as the vector projection of P on G.

As described in the '964 application, the left side of FIG. 8B is a schematic illustration of the portions of the embodiments of FIGS. 1A and 2A which have a determinative polarization component to enable the creation of the electrostatic potential barrier formed of Group III- or Group II-polar materials.

As described in the '964 application, the left side of FIG. 8B is directed preferred embodiments in which the p-type layer is grown closest to the substrate. The right side of FIG. 8B is directed preferred embodiments in which the n-type layer is grown closest to the substrate. Referring to the case of the p-type layer grown closest to the substrate, for Group III- or Group II-polar materials, to enable the creation of the electrostatic potential barrier, the absolute value of the polarization P2, which correlates to the barrier regions 14 in FIGS. 1A, 1B, 2A, and 2B, must be greater than the absolute value of the polarization P1 (which correlates to the absorption/multiplication region 13) and the absolute value of the polarization P3 (which correlates to the region 15 in FIG. 1A and region 16 in FIG. 2A) taken individually. The scalar projection S2 of the region 14 must be less than zero and must be less than the scalar projections S1 (correlating to region 13) and 53 (which correlates to the region 15 in FIG. 1A and region 16 in FIG. 2A), taken individually.

As described in the '964 application, referring to the preferred embodiment p-SiC/i-SiC/AlN/AlGaN structure of FIG. 1A, |P2|>|P1|,|P3| where P2 is the polarization in AlN barrier region 14, P3 is the polarization in AlGaN transparent window region 15, P1 is the polarization in SiC multiplication/absorption region 13, and theta=180 degrees, which applies to group III polar materials. Hence, the cosine is equal to −1 and this implies that S₂=−|P2|, S1=−|P1|, S3=−|P3| and since larger negative numbers are smaller than smaller negative numbers=>S2<S1,S3.

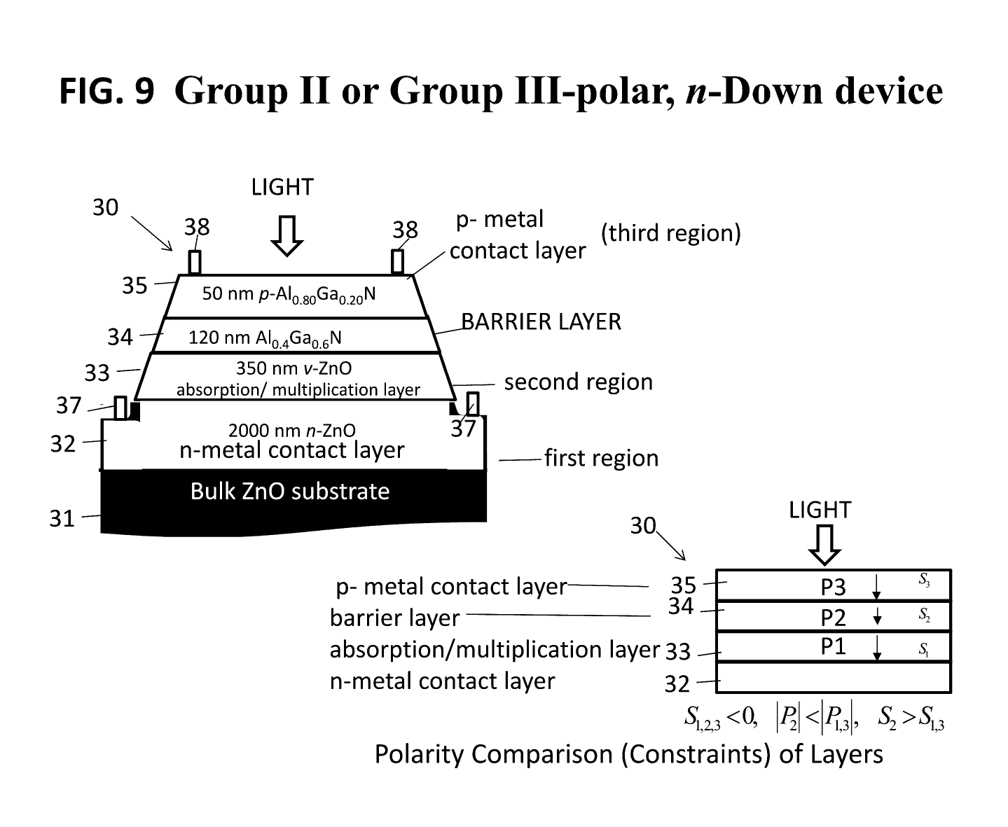

As described in the '964 application, with reference to the right side of FIG. 8B, referring to the case of the n-type layer grown closest to the substrate, for Group III- or Group II-polar materials, to enable the creation of the electrostatic potential barrier, the absolute value of the polarization P₂, which correlates to the barrier regions 14 in FIG. 9A, must be less than the absolute value of the polarization P₁ (which correlates to the absorption/multiplication region 13) and the absolute value of the polarization P₃ (which correlates to the region 16 in FIG. 9A) taken individually. The scalar projection S₂ of the region 14 must be less than zero and must be greater than the scalar projections S₁ (correlating to region 13) and S₃ (which correlates to the region 16 in FIG. 9A), taken individually.

As described in the '964 application, ith reference to the right side of FIG. 8B, the alternate preferred embodiment 30 of FIG. 9A may be, for example, a III-Nitride/ZnO pin structure grown on bulk ZnO substrate 31 comprising a n-type semiconductor metal contact region or layer 32, which may be, for example, a 2 μm thick n-ZnO layer doped 2×10¹⁹ cm⁻³, an absorption/multiplication region or layer 33, which may be, for example, a 350 nm thick n⁻-ZnO layer lightly doped n-type 5×10¹⁵ cm⁻³, a transparent barrier region or layer 34, which may be, for example, a 120 nm thick Al_{0.2}Ga_{0.8}N layer 34, and a transparent window region 35 suitable for forming a p-metal contact, which may be, for example, a 50 nm thick p-Al_{0.40}Ga_{0.60}N layer. The thickness of barrier region or layer 34 may be as thin as 5 nm. The region or layer 35 is predominantly transparent to photons of interest for conversion in that these photons are generally not converted to electrons and holes in region or layer 35. The ZnO epitaxial layers or regions may be grown on n-type Zn-face ZnO substrate 31. The III-polar AlₓGa₍₁₋ₓ₎N epitaxial layers or regions may be heteroepitaxially grown by plasma assisted molecular beam epitaxy at 780° C. directly upon the ZnO epitaxial layers or regions. Epilayers can be fabricated into, for example, 250 μm diameter, circular mesas with seven degree beveled sidewalls. The p-AlₓGa₍₁₋ₓ₎N Ohmic contact 38 comprises of a stack comprising 30 nm Ni/100 nm Au metallization scheme while the n-ZnO Ohmic contact 37 consists of 30 nm Ta/20 nm Au. The selection of metals for the contact layer depend upon metal work-function, adhesion, as well as impurity diffusion considerations. There are a number of Ohmic contacts schemes to p-AlGaN and n-ZnO reported in the literature. The stacks that may be used are commonly employed. The constraint is that the contacts make a low resistance Ohmic contact; in contrast to a Schottky contact.

Referring now to the preferred embodiment n-ZnO/i-ZnO/AlₓGa₍₁₋ₓ₎N/p-Al_{y}Ga_{(1-y)}N, where y>x structure on ZnO substrate 31 of FIG. 9A, |P2|<|P1,|,|P3| where P2 is the polarization in AlₓGa₍₁₋ₓ₎N barrier region 34, P3 is the polarization in p-Al_{y}Ga_{(1-y)}N transparent window region 35, P1 is the polarization in ZnO multiplication/absorption region 33, and theta=180 degrees, which applies to group III or group II polar materials. Hence, the cosine is equal to −1 and this implies that S₂=−|P2|, S1=−|P1|, S3=−|P3| and since larger negative numbers are smaller than smaller negative numbers=>S2>S1, S3. In this case, the preferred embodiment acts as a barrier for hole transport from the lower valleys in the valence band, and therefore as a hole filter rather than an electron filter because it passes higher energy holes or holes in higher energy valleys created by higher energy photons in the multiplication/absorption region 33, thereby operating to define a predetermined wavelength range of the photodetector.

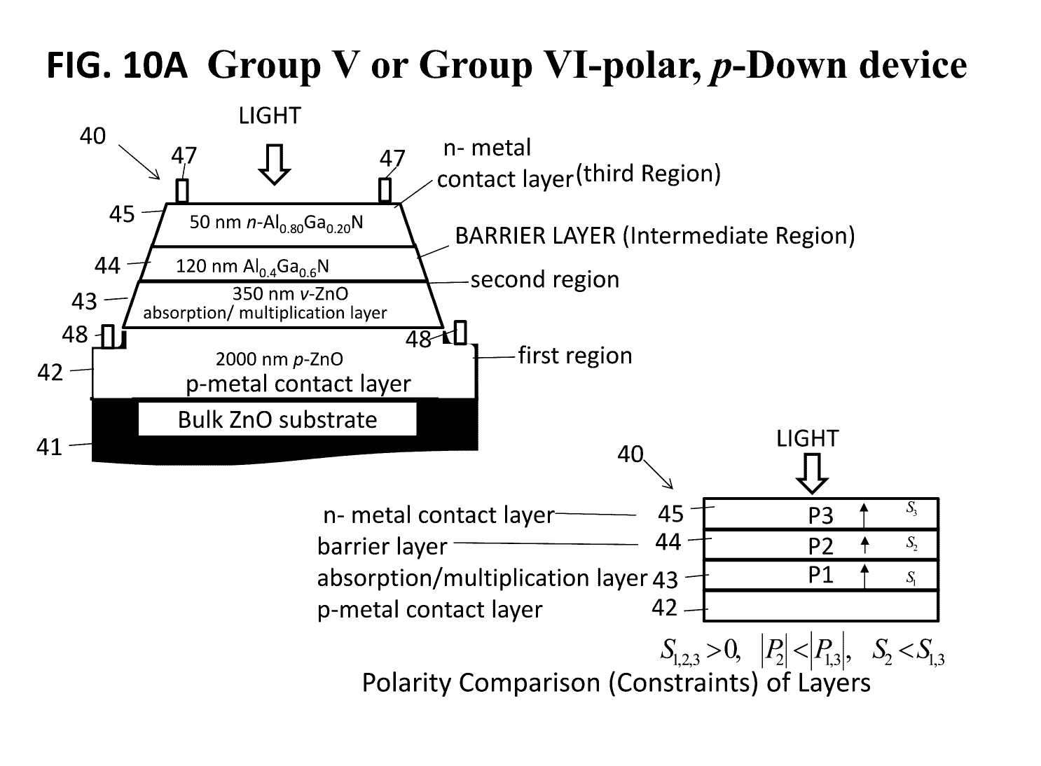

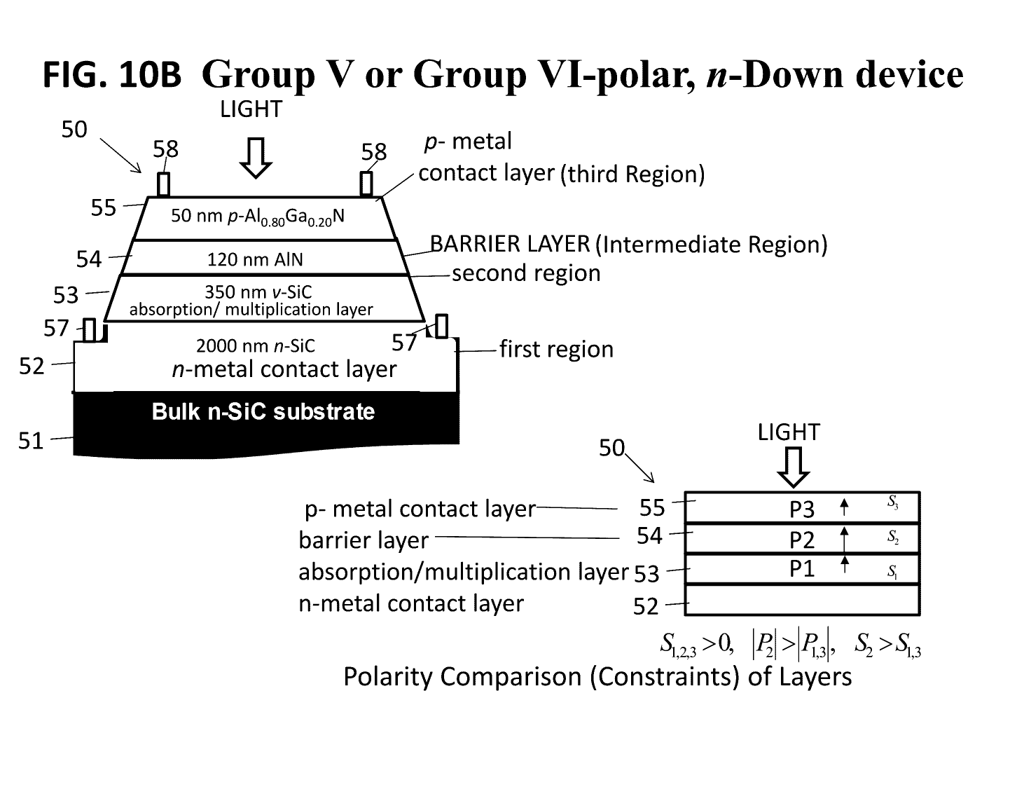

As described in the '964 application, FIG. 8C is a schematic illustration of the portions of the alternative embodiments of FIGS. 10A and 10B which have a determinative polarization component to enable the creation of the electrostatic potential barrier formed of Group V- or Group VI-polar materials. The left side of FIG. 8C is directed preferred embodiments in which the p-type layer is grown closest to the substrate. The right side of FIG. 8C is directed preferred embodiments in which the n-type layer is grown closest to the substrate. Referring to the case of the p-type layer grown closest to the substrate, for Group V- or Group VI-polar materials, to enable the creation of the electrostatic potential barrier, the absolute value of the polarization P₂, which correlates to the barrier region 44 in FIG. 10A, must be less than absolute value of the polarization P₁ (which correlates to the absorption/multiplication region 43) and the absolute value of the polarization P₃ (which correlates to the region 45 in FIG. 10A) taken individually. The scalar projection S₂ of the region 44 must be greater than zero and must be less than the scalar projections S₁ (correlating to region 43) and S₃ (which correlates to the region 45 in FIG. 10A), taken individually.

As described in the '964 application, with reference to the left side of FIG. 8C, the alternate preferred embodiment 40 of FIG. 10A may be, for example, a III-Nitride/ZnO nip structure grown on bulk ZnO substrate 41 comprising a p-type semiconductor metal contact region or layer 42, which may be, for example, a 2 μm thick p-ZnO layer doped 2×10¹⁹ cm⁻³, an absorption/multiplication region or layer 43, which may be, for example, a 350 nm thick p⁻-ZnO layer lightly doped p-type 5×10¹⁵ cm⁻³, a transparent barrier region or layer 44, which may be, for example, a 120 nm thick Al_{0.2}Ga_{0.8}N layer 44, and a transparent window region 45 suitable for forming a n-metal contact, which may be, for example, a 50 nm thick n-Al_{0.40}Ga_{0.60}N layer. The thickness of barrier region or layer 44 may be as thin as 5 nm. The region or layer 45 is predominantly transparent to photons of interest for conversion in that these photons are generally not converted to electrons and holes in region or layer 45. The ZnO epitaxial layers or regions may be grown on n-type O-face ZnO substrate 41. The V-polar AlₓGa₍₁₋ₓ₎N epitaxial layers or regions may be heteroepitaxially grown by plasma assisted molecular beam epitaxy at 780° C. directly upon the ZnO epitaxial layers or regions. Epilayers can be fabricated into, for example, 250 am diameter, circular mesas with seven degree beveled sidewalls. The n-AlₓGa₍₁₋ₓ₎N Ohmic contact 47 comprises of a stack comprising Ti 10 nm/Al 100 nm/Ni 30 nm/Au 50 nm metallization scheme while the p-ZnO Ohmic contact 48 consists of 30 nm Ni/100 nm Au. The selection of metals for the contact layer depend upon metal work-function, adhesion, as well as impurity diffusion considerations. There are a number of Ohmic contacts schemes to n-AlGaN and p-ZnO reported in the literature. The stacks that may be used are commonly employed. The constraint is that the contacts make a low resistance Ohmic contact; in contrast to a Schottky contact.

Referring now to the FIG. 10A example, additional preferred embodiment p-ZnO/i-ZnO/AlₓGa₍₁₋ₓ₎N/n-Al_{y}Ga_{(1-y)}N, where y>x structure on ZnO substrate 41, the polarization relationship is |P2|<|P1,|P3| where P2 is the polarization in AlₓGa₍₁₋ₓ₎N barrier region 44, P3 is the polarization in n-Al_{y}Ga_{(1-y)}N transparent window region 45, P1 is the polarization in ZnO multiplication/absorption region 43, and theta=0 degrees, which applies to group V or group VI polar materials. Hence, the cosine is equal to 1 and this implies that S₂=|P2|, S1=|P|, S3=|P3| with S2<S1, S3. In this case, the preferred embodiment acts as a barrier for electron transport from the lower valleys in the conduction band of the multiplication/absorption region 43, and therefore as an electron filter because it passes higher energy electrons or electrons in higher energy valleys created by higher energy photons, thereby operating to define a predetermined wavelength range of the photodetector.

With reference to the right side of FIG. 8C, referring to the case of the n-type layer grown closest to the substrate, for Group V- or Group VI-polar materials, to enable the creation of the electrostatic potential barrier, the absolute value of the polarization P₂, which correlates to the barrier region 54 in FIG. 10B, must be greater than the polarization P₁ (which correlates to the absorption/multiplication region 53) and the polarization P₃ (which correlates to the region 55 in FIG. 10B) taken individually. The scalar projection S₂ of the region 54 must be greater than zero and must be greater than the scalar projections S₁ (correlating to region 53) and S₃ (which correlates to the region 55 in FIG. 10B), taken individually.

As described in the '964 application, FIG. 10B is an illustration of an alternate preferred embodiment 50, a Group V or Group VI-polar, n-down photodetector. Alternative preferred embodiment 50 comprises a substrate 51 formed of, for example, silicon carbide. An n-metal contact region 52 may be formed of 2000 nm n-SiC. An absorption/multiplication region 53 may be, for example, formed of 350 nm v-SiC. Barrier region 54 is formed on the absorption/multiplication region 53. A p-metal contact region or layer 55 has terminals 58 positioned thereon. The n-SiC Ohmic contact 57 consists of Ni 35 nm/Ti 50 nm/Al 200 nm/Au 100 nm. while the p-AlₓGa₍₁₋ₓ₎N Ohmic contact 58 comprises of a stack comprising 30 nm Ni/100 nm Au metallization scheme. The contacts 57 and 58 are similar to element number 7 in the U.S. Pat. No. 8,269,223, FIG. 23, herein incorporated by reference. Referring now to the FIG. 10B additional preferred embodiment n-SiC/i-SiC/AlN/p-AlGaN structure has a polarization ratio of |P2|>|P1|, |P3| where P2 is the polarization in AlN barrier region 54, P3 is the polarization in AlGaN transparent p-contact layer 55, P1 is the polarization in SiC multiplication/absorption region 53, and theta=0 degrees, which applies to group V or group VI polar materials. Hence, the cosine is equal to 1 and this implies that S₂=|P2|, S1=|P1|, S3=|P3| with S2>S1, S3. In this case, the preferred embodiment acts as a barrier for hole transport from the lower valleys in the valence band, and therefore as a hole filter rather than an electron filter because it passes higher energy holes or holes in higher energy valleys created by higher energy photons in the multiplication/absorption region 53, thereby operating to define a predetermined wavelength range of the photodetector.

Although only one mesa is illustrated in FIGS. 1A and 2A, a group of mesas that form an array could be interconnected and used together. Using the teaching shown in conjunction with FIGS. 1A and 2A, one of ordinary skill in the art could create an array of mesas, in which case each mesa could produce a single pixel in an image array.

Optionally, the entire assembly (with the exception of the metal contact areas) is covered with a layer of SiO₂, deposited by plasma-enhanced chemical vapor deposition (PECVD).

It is important to note that the suppression observed in the response between 260-380 nm is associated with the energy band structure associated with the M- and L-valleys of SiC. The preferred embodiments of FIGS. 1A and 2A can be used to detect light in the solar blind region that is normally considered to be less than 280 nm at low elevations. Using different materials as an absorption/multiplication region will allow the fabrication of detectors that are sensitive with different bandwidths associated with suppression of the collection of photogenerated carriers that is related to their particular band structure. For example, detectors may be fabricated using an absorption\multiplication region 13 comprised of Zinc Oxide or Magnesium Zinc Oxide by employing a barrier layer 14 of suitable total polarization (see FIGS. 9 and 10A).

It is important to note that the absorption/multiplication regions or layers 13, 33, 43, and 53 may be composed of a single layer or a number of layers that may spatially separate absorption and multiplication or modify electric field distribution within the region.

Potential usages of the preferred embodiments of the present invention include replacing the photomultiplier tube (PMT) within compact biological agent identification systems based on fluorescence free Raman spectroscopy, employing these detectors within water monitoring systems, replacing UV enhanced Si avalanche photodiodes within sniper fire weaponry detections systems; replacing PMTs and UV enhanced Si avalanche photodiodes in UV communications systems. Solar-blind ultraviolet detectors are useful for bioagent detection-identification systems for hospitals, and commercial HVAC systems as well as compact water quality monitoring systems for disaster relief workers and outdoor enthusiasts.

As described in the '964 application, system designers requiring high sensitivity and low noise UV detectors for spectroscopy and single photon counting have the option of employing PMTs or UV enhanced Si APDs. Generally speaking. PMTs have significant shortcomings including high cost, bulky packaging, requiring high voltage for operation (>1000 V) and cooling for high sensitivity. UV enhanced Si APDs can provide high gain, but can have high dark current and significant long wavelength response that can make them suboptimal for certain applications. SiC APDs are still in the developmental stage but they can have high gain and very low dark current. However, these devices exhibit low quantum efficiencies at long wavelength approaching the band gap (˜380 nm) because of poor absorption due to the indirect band gap of SiC. Most of these detectors are inherently broad band thus expensive optical filtering is often required to narrow the spectral response to a desired band such a solar-blind or visible-blind. Operation in the solar blind region is useful for imaging/detecting human-generated phenomena against a solar background. These devices are critical for developing systems for sniper fire detection, UV communications, biological-chemical agent identification and detection, and water quality monitoring.

In contrast, the preferred embodiments of the invention described in the '964 application utilize a novel approach to provide a long wavelength cut-off to the photoresponse of a photodetector that leverages the polarization interface charge that occurs at the heterointerfaces between materials with different polarity. By inserting an appropriate barrier layer within the photodetector design, the long wavelength response can be significantly suppressed. One embodiment of particular military and commercial interest is the development of solar-blind or visible-blind detectors with no, or greatly reduced, optical filter requirements. A solar-blind AlₓGa₁₋ₓN/AlN/SiC Electron Filter Photodetector (EFP) (illustrated schematically in FIG. 1A) has been demonstrated that has significant cut-off of long wavelength response at 260 nm. These devices are attractive as a replacement for PMTs and UV enhanced Si APDs for system designers because of (1) lower cost—an AlₓGa₁₋ₓN/AlN/SiC EFP can be produced at significantly lower cost than PMTs; (2) room temperature operation—An AlₓGa₁₋ₓN/AlN/SiC EFP can be operated at room temperature, while PMTs often require thermoelectric cooling depending upon the sensitivity required, and (3) Fragility-PMTs require the cathode detection material and dynode gain medium to be encased within a vacuum sealed tube. This packaging is inherently more fragile than that employed for semiconductor based detectors; (4) Solar/Visible blind detection—An AlₓGa₁₋ₓN/AlN/SiC EFP can be made inherently visible/solar blind by tuning the relative AlN, InN and GaN compositions of the III-Nitride barrier and contact layers. In contrast, UV-enhanced Si APDs require external filters that can be costly depending upon the level of rejection required. AlₓGa₁₋ₓN/AlN/SiC EFPs (shown schematically in FIG. 1A) exhibit peak unity gain quantum efficiency (QE) of ˜76% at 242 nm that is significantly higher than what is observed for conventional homogeneous SiC pin photodiodes and a long wavelength cut-off at 260 nm.

Deep Ultraviolet-Avalanche Photodetector with n-n⁻-p Diode Structure Having High Responsitivy Using a Minimally Sized Undepleted Zone Adjacent the Illuminated Surface of the N+ Material with Depletion of Remainder of the N+ Material Using Reverse Bias

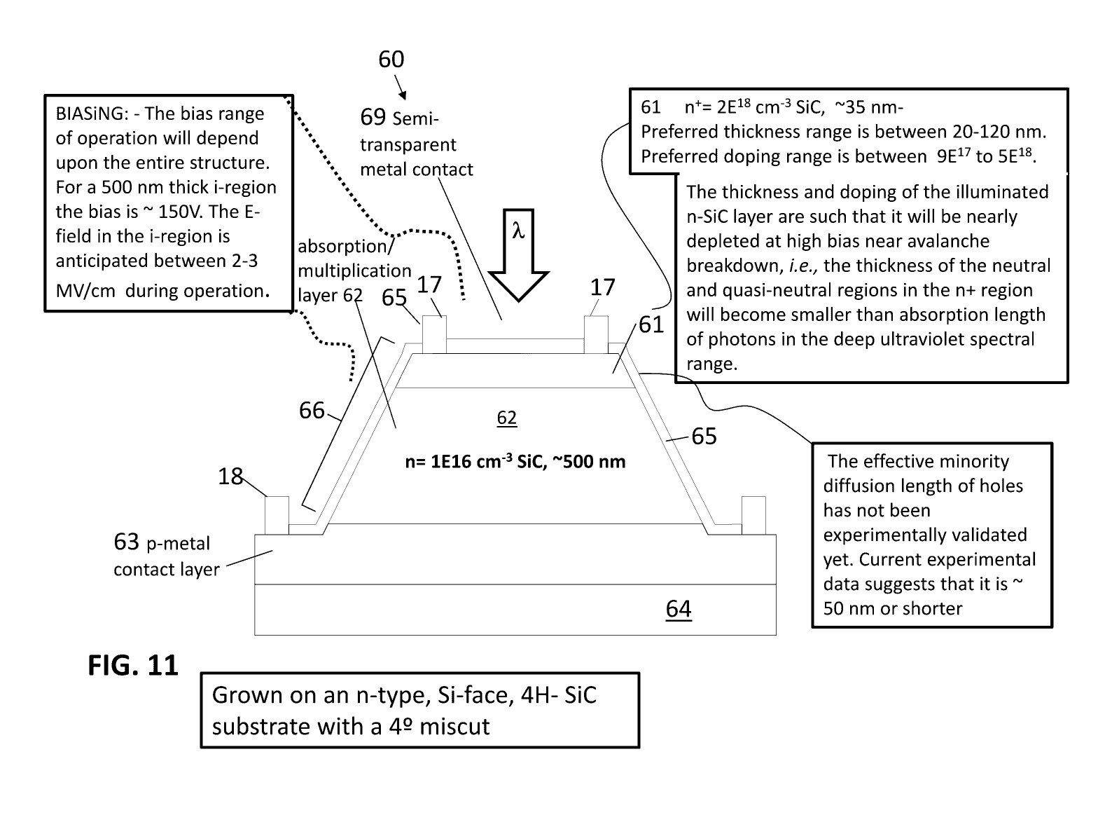

When referring to a semiconductor structure composed of more than one layer doped with a particular type, a “⁻” will be used to denote that one layer has lower doping than another. For example, an n⁻ layer will have lower n-type doping than an n-layer in an n⁻-n-semiconductor structure. Referring now to FIG. 11, shown is an alternate preferred embodiment 60 of an n-n⁻-p SiC avalanche photodiode that exhibits high responsivity at wavelengths shorter than 280 nm, gain and low dark current at high reverse bias, just short of avalanche breakdown. As a result, these devices are ideal for realizing a highly sensitive single-photon-counting avalanche photodiode (SPAD) in the deep ultraviolet spectrum (λ<260 nm) for the first time, based on SiC.

The SiC n-n⁻-p structure or photodiode 60 includes an approximately 35 nm thick n+-layer 61 doped with 2×10¹⁸ cm⁻³ nitrogen atoms overlying a 480-500 nm thick n⁻ layer, or i-layer, 62 doped with 1×10¹⁶ cm⁻³ nitrogen atoms which in turn overlies a 2000 nm thick p-layer 63 doped with an Aluminum concentration of 2×10¹⁸ cm⁻³. The structure is grown on an n-type, Si-face, 4H—SiC substrate 64 with a 4° miscut. The avalanche photodiodes 60 may have a 50-250 μm-diameter circular mesa 65 and seven degree beveled sidewalls 66.

The thickness of the n⁻-layer 62 may be varied to modify the gain and dark current within the diode for a given reverse bias. The thickness of the n⁻-layer 62 may range from 250 nm to 960 nm, with the lower end of the range resulting in reduced reverse bias required for avalanche breakdown but likely reduced gain and increased dark current. In contrast, the higher end of the range will likely result in higher gain and lower dark current but with a higher reverse bias required for avalanche breakdown.

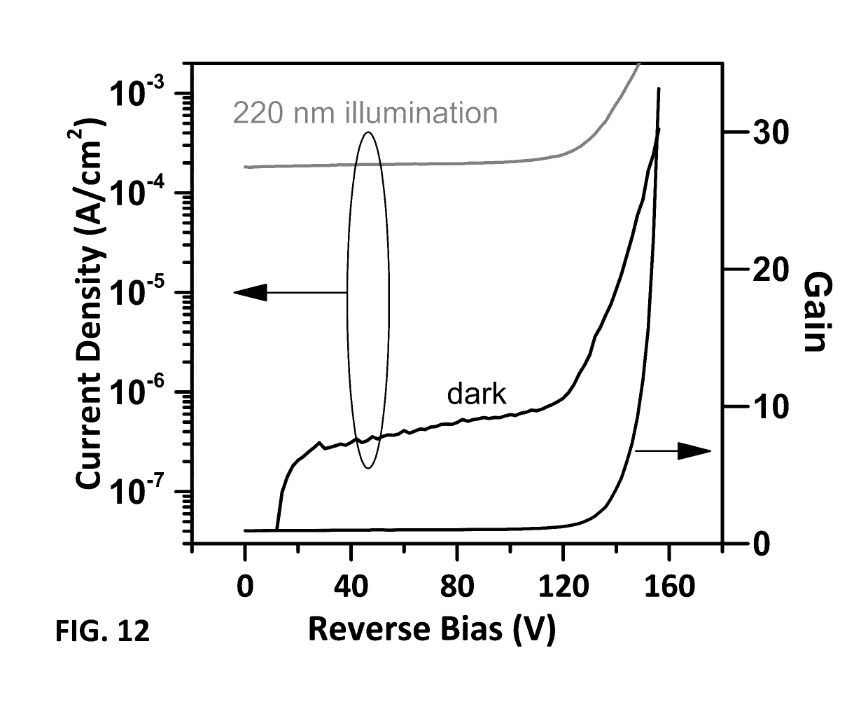

FIG. 12 shows the measured reversed bias IV characteristics of the fabricated deep ultraviolet-avalanche photodetector (DUV-APD). The measured dark current increases slowly below 120V bias and then increases more rapidly to ˜153V. It is important to note that the diameter of the tested devices were large, ˜200 μm, in comparison to what has been investigated for GaN based APDs. See, for example, Y. Zhang, D. Yoo, J. Limb, J. Ryou, R. D. Dupuis, and S. Shen, “GaN ultraviolet avalanche photodiodes fabricated on free-standing bulk GaN substrates,” Phys. stat. sol. (c) 5, No. 6, 2290-2292 (2008), herein incorporated by reference.

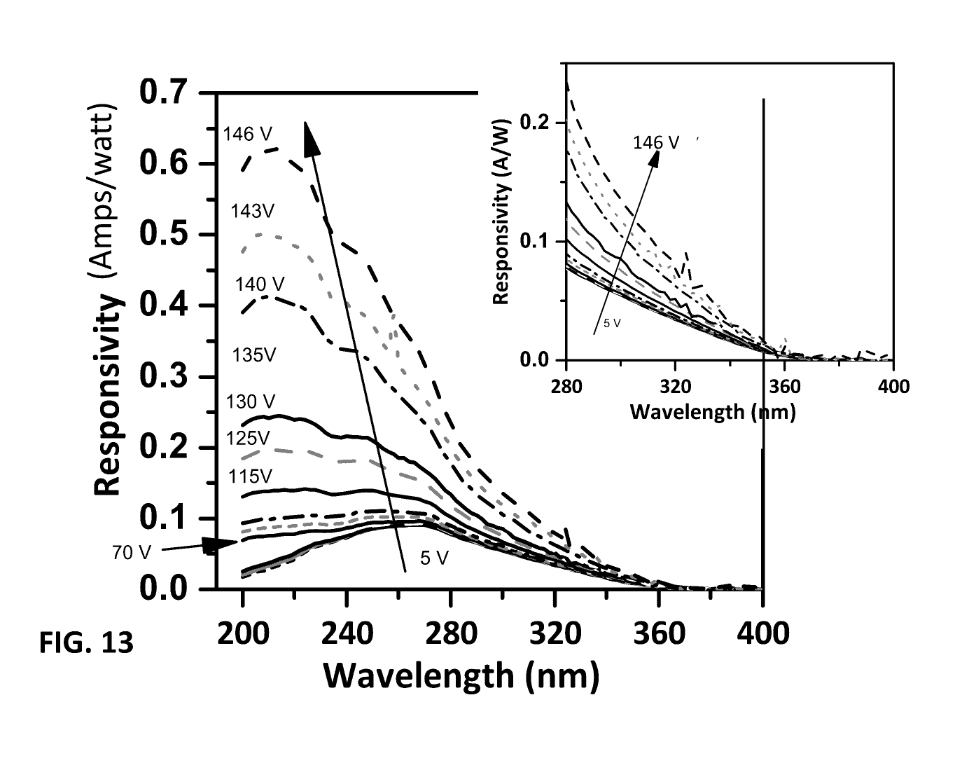

FIG. 13 shows the measured spectral response from a fabricated deep ultraviolet avalanche photodetector 60 under 100 nW illumination as function of increasing reverse bias from 5 to 146V, and thus short of avalanche breakdown at ˜150-160V. At low bias the photoresponse peaks at ˜265 nm, corresponding to a unity-gain quantum efficiency of ˜41% that is reduced due to absorption in the semi-transparent top metal contact, and drops off at shorter wavelengths. These results are typical of what is generally observed for SiC APD devices. At increasing reverse bias, the responsivity increases and the peak response shifts to ˜212 nm at the highest bias investigated, i.e. 146V. This change in the shape of the spectral response can be explained by considering two phenomena that occur with increasing reverse bias, 1) the depletion of the top-illuminated n⁺-layer and 2) spectrally inhomogeneous gain in this structure.

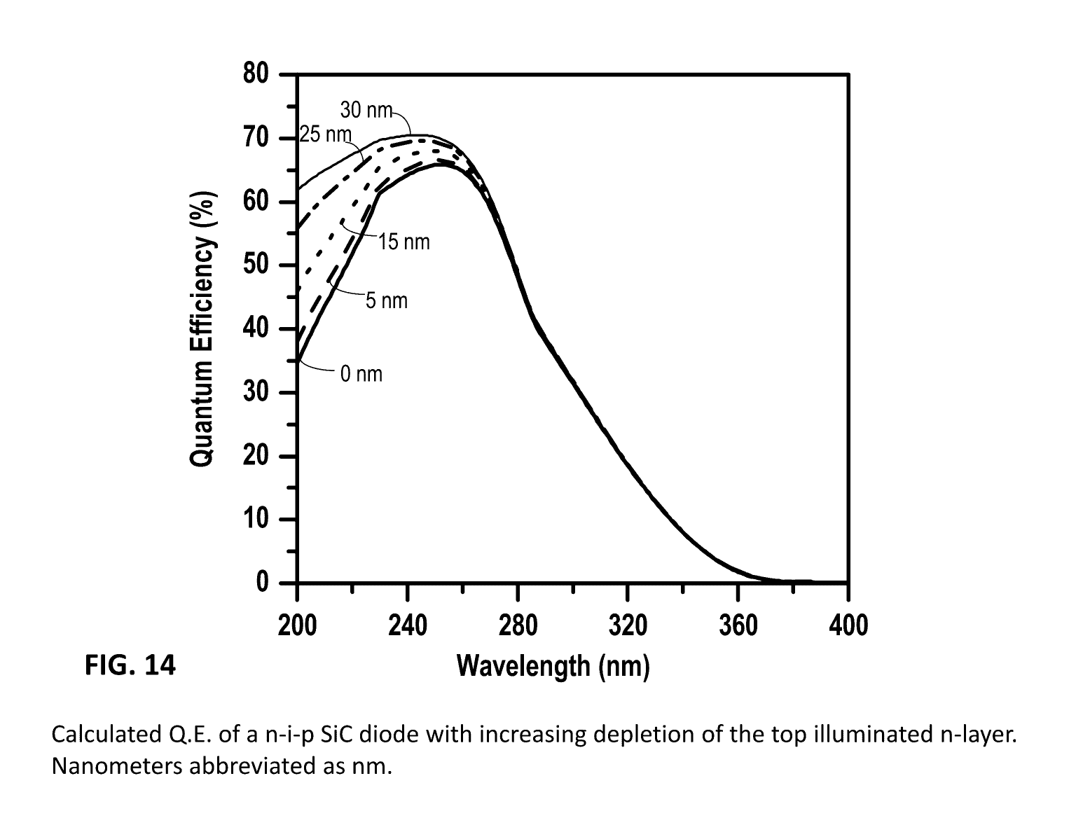

At low reverse bias there is no increase theoretically expected in the measured photocurrent responsivity of an n-n⁻-p diode structure due to the very low E-field within the depletion region and therefore the lack of gain associated with impact ionization. This understanding is consistent with the relatively constant response observed in the n-n⁻-p structure at wavelengths longer than ˜280 nm initially with increasing reverse bias (FIG. 13 inset). However, a measurable increase in the short wavelength response even initially with increasing reverse bias can be explained by an increase in the depletion width of the n-n⁻-p with increasing reverse bias. While both the n-side and p-side depletion width are expected to increase with increasing bias, the increase on the n-side will be larger due to the lower doping in the n-region. The increase in depletion width, primarily on the n-side, is expected to have more significant impact on the collection of carriers generated by deep ultraviolet photons that are strongly absorbed in the top illuminated n-layer, and are generally lost to surface recombination. Increasing the depletion width should enhance the DUV photoresponse by increasing the number of photo-generated holes collected through drift as well as improving the efficiency for collection of these carriers by diffusion through a reduction of the distance these carrier need to diffuse through the top n-layer. This interpretation is further supported by calculating the expected quantum efficiency from an n-n⁻-p SiC diode with increasing depletion of n-layer as shown in FIG. 14. Consistent with experimentally observed trends, the response in the DUV spectral range is found to increase, while it remains relatively constant in the NUV spectral range. Further support for this explanation is found in the qualitative agreement between the measured response observed at ˜70 V in the DUV-APD and that of a metal-i-p structure that has been previously reported in A. V. Sampath, L. E. Rodak, Y. Chen, Q. Zhou, J. C. Campbell, H. Shen; M. Wraback, “High quantum efficiency deep ultraviolet 4H—SiC photodetectors”, Electronics Letters, Volume 49, Issue 25, 5 Dec. 2013, p. 1629-1630, herein incorporated by reference. It is important to note that the photoresponse of the DUV-APD was measured in the spectral range between 200-400 nm due to limitations in the experimental setup and that this device has sensitivity at wavelengths shorter than 200 nm. It is also important to note that these devices were biased short of avalanche breakdown due to limitations in the experimental test setup for probing the devices. These devices can in principal be reverse biased at or above avalanche breakdown.

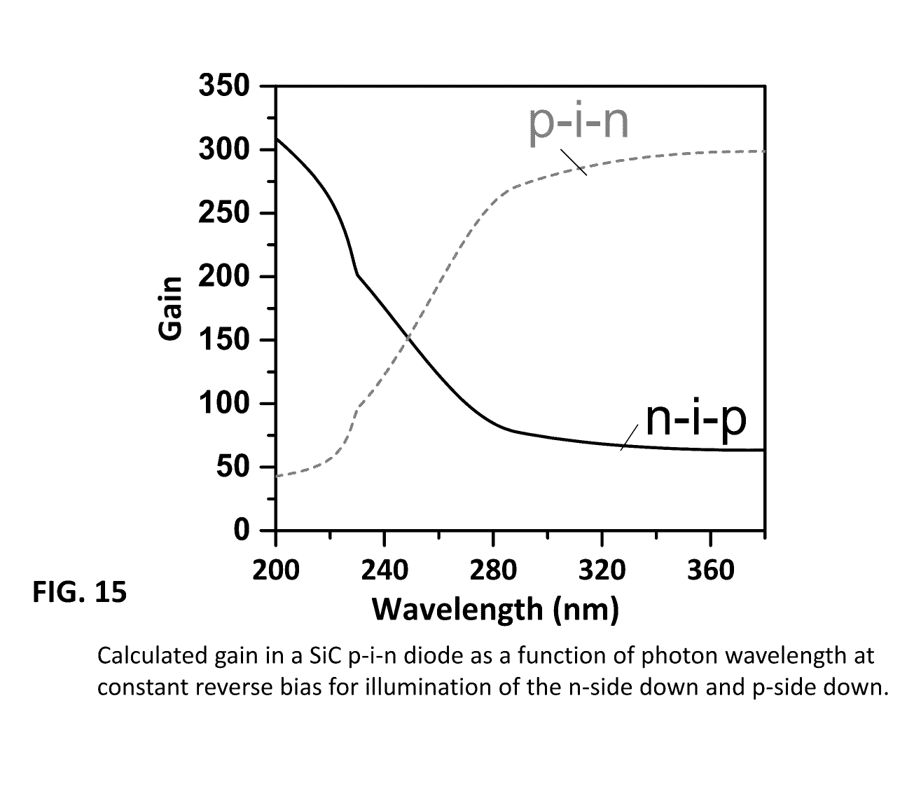

For increasing bias above ˜70V an increase in photoresponse is observed over a wider spectral range. This increase can be attributed to on-set of gain within the DUV-APD due to impact ionization. However, this enhancement is significantly stronger in the DUV spectral range resulting in a shift in the peak response to ˜212 nm at the highest bias investigated. The spectral inhomogeneity in the observed gain can be explained by considering the ˜10× larger impact ionization coefficient for holes (βₚ) over electrons (αₙ) as well as the significantly stronger absorption of photons in the deep ultraviolet spectral range. Previously we have shown that the photocurrent generated in an n-i-p SiC structure (i.e. illuminated from the n-side) in the DUV spectrum is dominated by carriers generated from photons absorbed in the top-illuminated n-layer, while the near band-gap response has significant contribution from carriers generated in both the i- and bottom p-doped regions of the structure, as reported in A. V. Sampath, L. E. Rodak. Y. Chen, Q. Zhou. J. C. Campbell, H. Shen and M. Wraback, “Enhancing The Deep Ultraviolet Performance Of 4H—SiC Based Photodiodes” ECS Transactions, 61 (4) 227-234 (2014), herein incorporated by reference. As the principal carrier associated with gain for carriers photogenerated in the n-layer is a hole while that for carriers photogenerated in the p-layer is an electron, and the impact ionization coefficient of holes is ˜10× that of electrons, the significantly shorter absorption length for DUV photons results in the generation of holes that have a maximized path length through the gain region. In contrast, longer wavelength photons are absorbed more uniformly throughout the structure, resulting in gain from a mix of photogenerated electrons and holes traveling, on average, a shorter distance that necessarily results in lower gain. A calculation on the gain expected for an n-side (n-i-p) and a p-side illuminated (p-i-n) SiC diode having a 480 nm thick i-region demonstrates this trend, as shown in FIG. 15. The “spectrally inhomogeneous gain” shown in FIG. 15 results from gain arising primarily from impact ionization multiplication of holes and their spatial distribution in the device structure associated with the wavelength dependent absorption depth for photogeneration of carriers. The absorption depth refers to a thickness within a layer wherein 1−1/e (e=natural logarithm=0.368);); i.e., approximately, approximately 63% of % of the photons at the detection wavelength of interest are absorbed according to Beer's Law. For an n-i-p structure, the gain at 200 nm is ˜310 while at 360 nm it is ˜75. In contrast for a p-i-n structure the opposite is the case, gain at 360 nm is ˜6× greater than gain at 200 nm. This phenomena is related to 1) the ionization rate of the principal carrier that is being multiplied in the gain region and 2) where the photons are absorbed within the structure, which effects the distance photogenerated carriers travel inside the gain region. As holes have a higher ionization rate than electrons in 4H—SiC and deep ultraviolet photons are absorbed very close to the surface, carriers generated by photons at these wavelengths have higher gain in the n-i-p structure. This phenomenon is partially responsible for the emerging 212 nm peak observed in FIG. 13 at biases above 130V. Calculation of the expected response in our DUV-APD shown in FIG. 16 demonstrates the same trends observed experimentally at high bias near avalanche breakdown. Specifically, the near flat spectral response observed at moderate bias over a wide spectral range from 200-280 nm becomes a more peaked response around 220 nm.

The operating reverse bias point for the photodiode will generally be application specific. For applications requiring high sensitivity, the diode may be biased to have high gain in the multiplication layer 62. For operation in a single photon counting mode, the diode may be operated near or above the avalanche breakdown voltage. This corresponds to an E-field in the multiplication region 62 of 2-3 MV/cm for SiC or a reverse bias of ˜150V for a 500 nm thick region 62. The doping in this region will generally be sufficiently low to allow for a large and uniform electric field throughout such as n=1×10⁻¹⁶ cm⁻³ for the photodiode 60.

The thickness and doping of the illuminated n-region 61 will be designed so that it is sufficiently depleted at the reverse bias operating point such that DUV photons are absorbed within this region. However, region 61 cannot be biased to full depletion as this will cause a large increase in dark current in the photodiode that can reduce detector performance. For photodiode 60 the n-region preferred thickness range is between 20-120 nm and preferred n-type doping range in this region is 9×10¹⁷ to 5×10¹⁸ cm⁻³.

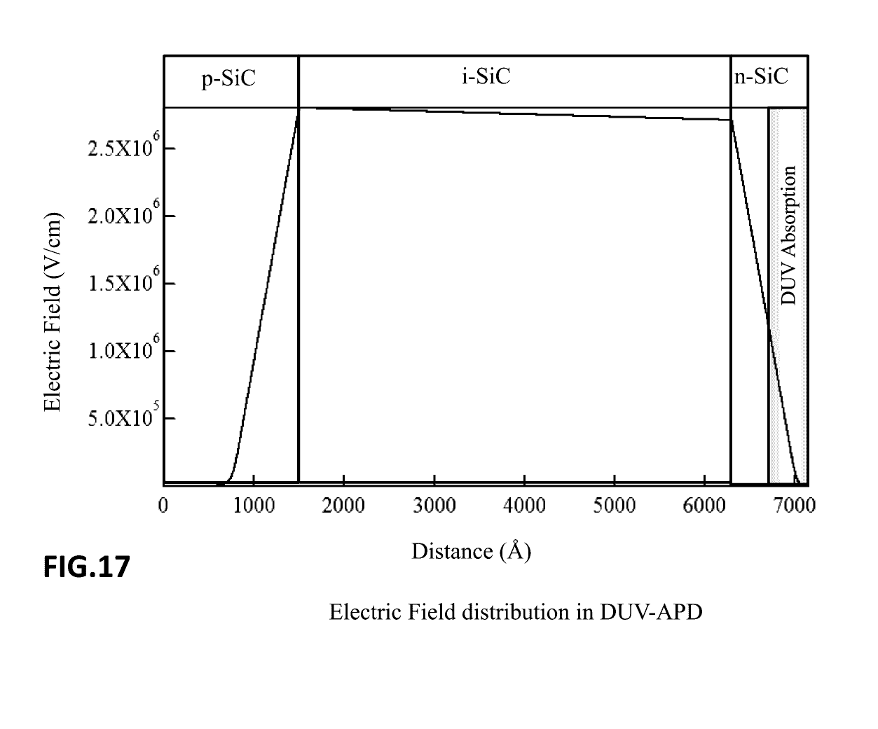

One advantage of this design is the low noise in the DUV spectrum that is expected due to the spatial separation of the absorption and multiplication regions in the structure for photons in this spectral range, as illustrated in FIG. 17. As DUV photons are primarily absorbed and photocarriers generated in the lower E-field n⁺-region of this structure due to strong absorption in this spectral range, while carrier multiplication primarily occurs in the n⁻-SiC region, single carrier hole multiplication can be achieved in this wavelength range due to the long transit path of holes through the high electric field multiplication region, as compared to electrons, which have a significantly shorter path primarily through a diminishing electric field in the n⁺-SiC region. As a result, this structure should yield lower excess noise for operation in this spectral range without the use of a thick doped charge layer traditionally employed in a separate absorption charge multiplication avalanche photodiode, which can result in loss of detection efficiency resulting from diffusive transport in this region. See, for example, S. Soloviev, A. Vert, J. Fronheiser, P. Sandvik, “Positive Temperature Coefficient of Avalanche Breakdown Observed in a-Plane 6H—SiC Photodiodes,” Materials Science Forum Vols. 615-617 (2009) pp 873-876, herein incorporated by reference.

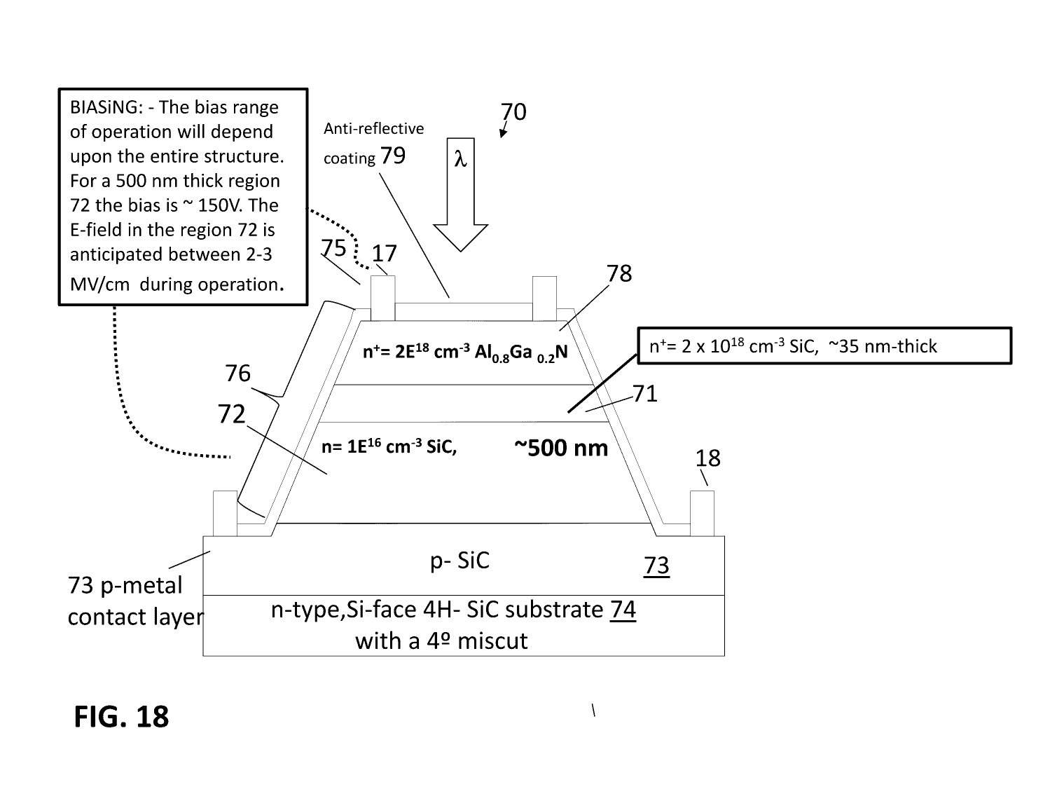

Moreover, the replacement of the semi-transparent window metal required to improve lateral E-field spreading in the current structure with a conductive and transparent wide band gap n-type semiconductor such as AlₓGa₁₋ₓN should improve on the unity gain quantum and single photon detection efficiencies of the current demonstrated device. The structure of this improved heterostructure is shown in FIG. 18.

FIG. 18 shows a schematic of an alternate preferred embodiment n⁺-AlGaN/n-n⁻-p SiC structure 70 comprising an approximately 100 nm thick n⁺-AlGaN layer 78 (third region) having an AlN mole fraction of ˜80% and doped with 5×10¹⁸ cm⁻³ silicon atoms, a 35 nm thick n⁺-SiC layer 71 doped with 2×10¹⁸ cm⁻³ nitrogen atoms (charge region), a 480-500 nm thick n⁻-SiC layer 72 doped with 1×10¹⁶ cm⁻³ nitrogen atoms and a 2000 nm thick p-SiC layer 73 doped with an Aluminum concentration of 2×10¹⁸ cm⁻³. The structure is grown on an n-type, Si-face, 4H—SiC substrate 74 with a 4° miscut. Avalanche photodiode embodiments 70 with 50-250 m-diameter circular mesas 75 and seven degree beveled sidewalls 76 were fabricated. The top n-type metal contact 17 comprises a Ti 10 nm/Al 100 nm/Ni 30 nm/Au 50 nm metallization scheme while the p-SiC Ohmic contact 18 comprises Ni 25 nm/Ti 35 nm/Al 100 nm/Ni 80 nm. An anti-reflective coating 79 was deposited in the window region to minimize losses associated with reflection of the illuminated light from the semiconductor surface.

The alternate preferred embodiment of the present invention shown in FIG. 18 comprises a heterostructure operable to extend the deep ultraviolet (DUV) response of SiC below 260 nm. Since the direct bandgap of aluminum gallium nitride (AlₓGₐ₍₁₋ₓ₎N) can be engineered from 3.4 eV to 6.1 eV depending on the AlN to GaN mole fraction, these alloys are employed as UV transparent, n-type contact windows (for example, the transparent window 78 in FIG. 18) to increase the absorption of high energy photons and concomitant photogeneration of carriers in the high electric field depletion region of the nip structure, as compared to the previously described structure with the semi-transparent metal contact that reduces the photon flux absorbed within the detector.

Preferred thickness range of the n-type AlGaN contact window layer is between ˜100-600 nm thick. The Al composition is preferably greater than 60% to insure transparency in the deep ultraviolet spectral range between 200-260 nm.

The use of AlₓGa₁₋ₓN alloys as a transparent n-type window increases the collection of photo-generated carriers created by absorption of high energy photons in the high-field SiC region. Peak QE of 76% at 242 nm has been measured in n-AlGaN/AlN/n⁻-SiC/p-SiC diodes shown in FIG. 3 and attributed to the minimization of the effects of surface states and absorption in heavily doped layers currently hindering homogeneous SiC devices. In this example, both the entire n-AlGaN/AlN structure acts as a transparent window. See, for example, L. E. Rodak, A. V. Sampath, C. S. Gallinat, Y. Chen, Q. Zhou, J. C. Campbell, H. Shen, and M. Wraback. “Solar-blind AlₓGa₁₋ₓN/AlN/SiC photodiodes with a polarization-induced electron filter.” Applied Physics Letters 103, no. 7 (2013): 071110, herein incorporated by reference.

This enhancement of the DUV response using a transparent window semiconductor is more clearly demonstrated in a device structure that does not have the barrier layer such as a p-i-SiC/n-AlₓGa₁₋ₓN photodiodes. FIG. 24 shows a schematic of an alternative preferred embodiment comprising an approximately 470 nm-thick n-AlₓGa₁₋ₓN layer 128 having ˜90% AlN by mole fraction, a 480-500 nm thick n⁻-SiC layer 121 doped with 1×10¹⁶ cm⁻³ nitrogen atoms and a 2000 nm thick p-SiC layer 123 doped with an Aluminum concentration of 2×10¹⁸ cm⁻³. The structure is grown on an n-type, Si-face, 4H—SiC substrate 124 with a 4° miscut. Avalanche photodiode embodiments 120 with 50-250 μm-diameter circular mesas 125 and seven degree beveled sidewalls 126 were fabricated. The top n-type metal contact 17 comprises a Ti 10 nm/Al 100 nm/Ni 30 nm/Au 50 nm metallization scheme while the p-SiC Ohmic contact 18 comprises Ni 25 nm/Ti 35 nm/Al 100 nm/Ni 80 nm. An anti-reflective coating 129 was deposited in the window region to minimize losses associated with reflection of the illuminated light from the semiconductor surface. For comparison, a 4H—SiC homojunction avalanche photodiode employing an illuminated recessed window to improve the EQE is provided from Handin Liu, Dion Mcintosh, Xiaogang Bai, Member, IEEE, Huapu Pan, Mingguo Liu, and Joe C. Campbell. “4H—SiC PIN Recessed-Window Avalanche Photodiode with High Quantum Efficiency” IEEE Photonics Technology Letters 20, NO. 18, (2008) 1551. This SiC APD structure consists of a 2 μm-thick n⁺ (4.5×10¹⁸ cm⁻³⁾ layer, a 480 nm-thick p- (Nₐ=1×10¹⁶ cm⁻³) layer, a 200 nm p (Nₐ=2×10¹⁸ cm⁻³⁾ layer, and a 200 nm p+(Nₐ=1×10¹⁹ cm⁻³) layer; the thickness of the top layer was reduced to ˜35 nm in the illuminated window through dry etching to reduce absorption in this region. The III-Nitride heterojunction and SiC homojunction devices were passivated with 200 nm and 220 nm thick silicon dioxide layers, respectively, which also act as an anti-reflection coating.

The photoresponse of the p-i-SiC/n-AlₓGa₁₋ₓN and homogenous SiC photodiodes are shown in FIG. 25. The recessed window SiC photodiode has a peak EQE of ˜60% at 260 nm and a sharp drop off in response at shorter wavelength (grey shaded curve). In contrast, the p-i-SiC/n-AlₓGa₁₋ₓN photodiode has a flatter response in DUV that exceeds 60% over a spectral range from 215-256 nm and a sharp cut-off at shorter wavelengths (black curve). This enhancement is a ˜10× enhancement in performance over comparable homogenous SiC photodiodes at the shortest wavelength and is attributed to the photogeneration of carriers within the depletion region of the heterojunction, where these carriers are more efficiently collected through drift over a typical p-i-n SiC photodiode structure that strongly relies on carrier diffusion.

The sharp short wavelength cutoff observed at 210 nm is attributed to the loss of photogenerated carriers within the neutral n-AlₓGa₁₋ₓN “window” layer; this results from the short effective carrier diffusion lengths within this region associated with the presence of dislocations arising from lattice mismatch inhibits the collection of photo-generated carriers through diffusion. This conclusion is consistent with what we have previously observed for the collection of photo-generated carriers within the GaN absorption region of a GaN/SiC separate absorption and multiplication APD, for which drift in an electric field is required. Anand V. Sampath, Ryan W. Enck, Q. Zhou, D. C. McIntosh, H. Paul Shen, J. C. Campbell, and Michael Wraback, “p-type Interface Charge Control Layers for Enabling GaN/SiC Separate Absorption and Multiplication Avalanche Photodiodes”, Applied Physics Letters, 101, (2012) 093506 This is further supported by measurement of the reflection spectrum from the heterojunction shown in FIG. 25 where the damping of the reflection oscillation associated with absorption in the n-AlₓGa₁₋ₓN layer correlates well with drop off in the short wavelength response of the heterojunction photodiode.

An additional benefit of an N-n-n⁻-p structure such as n⁺-AlGaN/SiC n-n⁻-p is that the n-type AlGaN layer (the N-layer) can be made arbitrarily thick to improve lateral conductivity and lateral electric field spreading that will improve uniformity over the detection area while also preventing punch-through of the E-field to the top metal contact. The presence of the n⁺-SiC layer will reduce the electric field at the hetero-interface and can potentially result in reduced dark current generation associated with heteroepitaxially generated defects. This may also make the structure more easily manufacturable, as the tolerances for designing the top n⁺-region for optimal DUV efficiency over a comparable n+-n⁻-p-SiC structure as shown in FIG. 11 while avoiding the metal contact punch-through effect would be relaxed.

For photodiode 70 the thickness and doping of the n-region 71 will be designed so that it is either fully depleted to the interface with the transparent window 78 or sufficiently depleted at the reverse bias operating point such that DUV photons are absorbed within this region. For photodiode 70 this occurs at thickness less than 100 nanometers, preferred thickness range is between 20-120 nm and preferred n-type doping range is 9×10¹⁷ to 5×10¹.

However, it should be noted that use of the n-type AlGaN transparent window can reduce the thickness of or eliminate the need for the more heavily doped n⁺-SiC layer as in preferred embodiment 120.

The operating reverse bias point for this photodiode will generally be application specific. For applications requiring high sensitivity, the diode may be biased to have high gain in the multiplication layer 72. For operation in a single photon counting mode, the diode may be operated near or above the avalanche breakdown voltage. This corresponds to an E-field in the multiplication region 72 of ˜2-3 MV/cm for SiC or a reverse bias of ˜150V for a 500 nm thick region 72. The doping in this region will generally be sufficiently low to allow for a large and uniform electric field throughout such as n=1×10⁻¹⁶ cm⁻³ for the photodiode 70.

While the preceding has focused on SiC and the collection of carriers generated by photons having energies corresponding to wavelengths shorter than 260 nm, the underlying principles are applicable to any semiconductor having a large surface recombination velocity and potentially a large surface band bending and where the carriers to be collected are generated near the surface of material. In this case, it is desirable to design the thickness and doping levels of the illuminated semiconductor layer such that this layer is sufficiently depleted so that the thickness of the remaining neutral and quasi-neutral regions are reduced to become near or shorter than the absorption depth of the photon to be detected at the reverse bias operating point of interest for the detector. This results in the beneficial case where carriers generated by these photons may be collected more efficiently through 1) drift within the depletion region and/or 2) reduced distance for carriers to diffuse from the illuminated neutral and quasi-neutral regions to the depletion region for collection. As a result, the performance of the detector will improve in the spectral range of interest. As the neutral and quasi-neutral region of the illuminated layer thickness reduces, the lateral conductance of the layer may decrease so as to prevent uniform lateral electric field spreading across the detection area of the photodetector. In this case, a semi-transparent metal contact layer can be deposited in the illumination area of the detector to improve the lateral electric field spreading. Another approach is to employ a sufficiently conductive semiconductor that is transparent in the spectral range of interest and make a metal contact to it around the periphery of the detection area to prevent absorption losses within the metal. The design choice of illuminating the n- or p-layer will be made based upon a number of consideration such as whether a particular carrier, electron or hole, has the higher ionization rate.

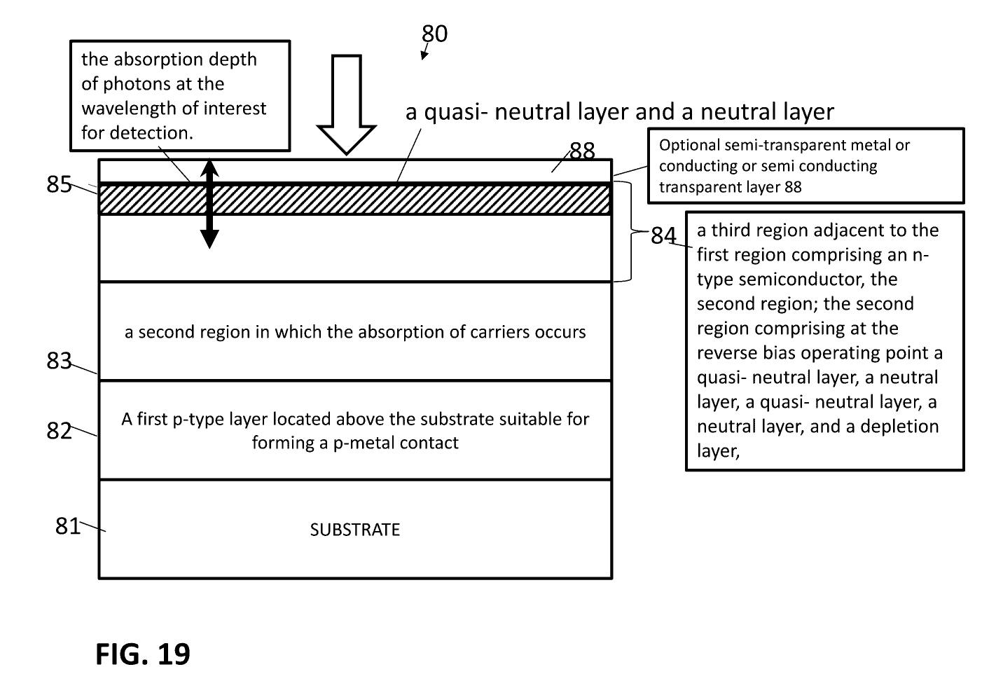

A schematic of such a device is shown in FIG. 19 for a device comprising an alternate preferred embodiment n-n⁻-p structure 80 deposited upon a substrate 81 and where the third n-layer 84 is illuminated with light. A second layer 83 in which multiplication occurs and a first p-type layer 82 are sandwiched between the substrate 81 and the n-layer 84. While not shown, it is assumed that the device is properly reverse biased at the operating point of interest for detection. For example, the device may be biased below the avalanche breakdown voltage and operating in linear mode with or without gain or Geiger mode. Alternatively the device may be biased above the avalanche breakdown voltage as is commonly done in Geiger mode to improve single photon detection efficiency. At this reverse bias the illuminated n-layer 84 will partially deplete so that the thickness of neutral and quasi-neutral region 85 within will be thinner than that of the n-layer 84. Since the width of the neutral and quasi-neutral region 85 will now be near or shorter than the absorption depth of the photon of interest for detection, the carriers generated by absorption of these photons will be more efficiently collected. This is due to more efficiently collecting these carriers through drift and/or the reduced length that carriers need to diffuse to the depletion region to be collected as current in the detector. As the lateral resistance of the neutral and quasi-neutral region 85 may now be large so as to prevent a uniform lateral electric field distribution across the device area, an optional transparent semiconductor or semi-transparent metal 88 is shown adjacent the illuminated n-layer 84. The n-layer (or third region) 84 adjacent to the second region comprises an n-type semiconductor. The third region 84 at the reverse bias operating point comprises a quasi-neutral layer, a neutral layer, and a depletion layer. Region 83 is denoted as the second region in which the multiplication of carriers occurs. A p-type layer 82 located above the substrate 81 is suitable for forming a p-metal contact. Represented by an arrow in FIG. 19 is the absorption depth of photons at the wavelength of interest for detection.

If a transparent wider band gap semiconductor is employed, then the structure can be described as an N-n-n⁻-p diode where the capital N is used to refer to the wider band gap semiconductor layer. It is important to note that in general the doping of n-layer can vary with thickness such that it is lower near the n-/n⁻-layer interface.

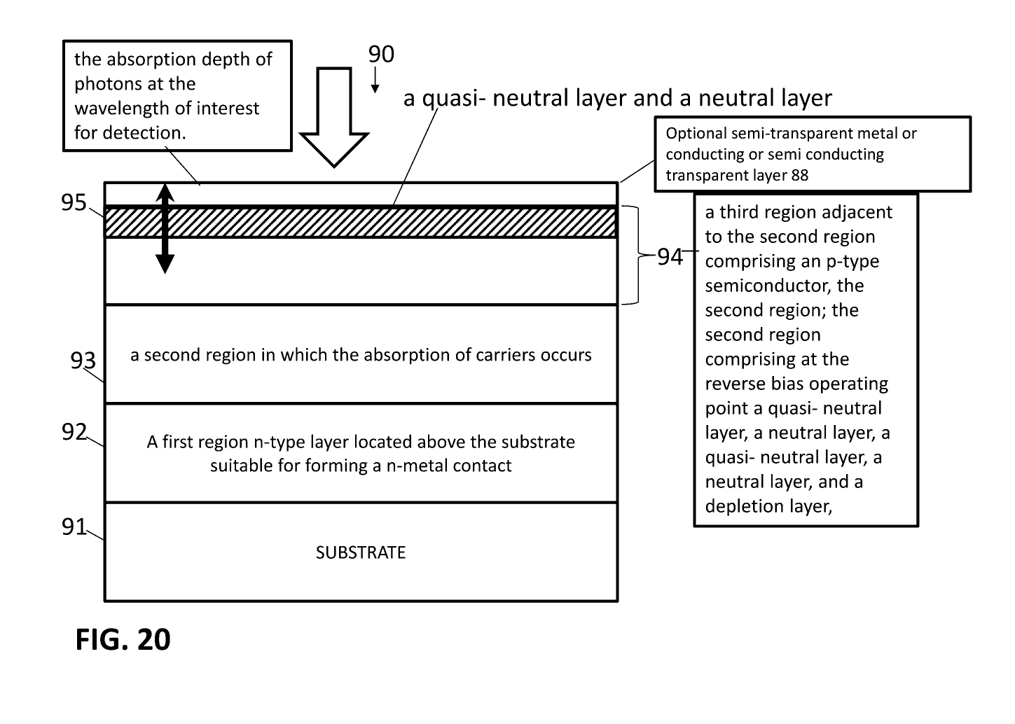

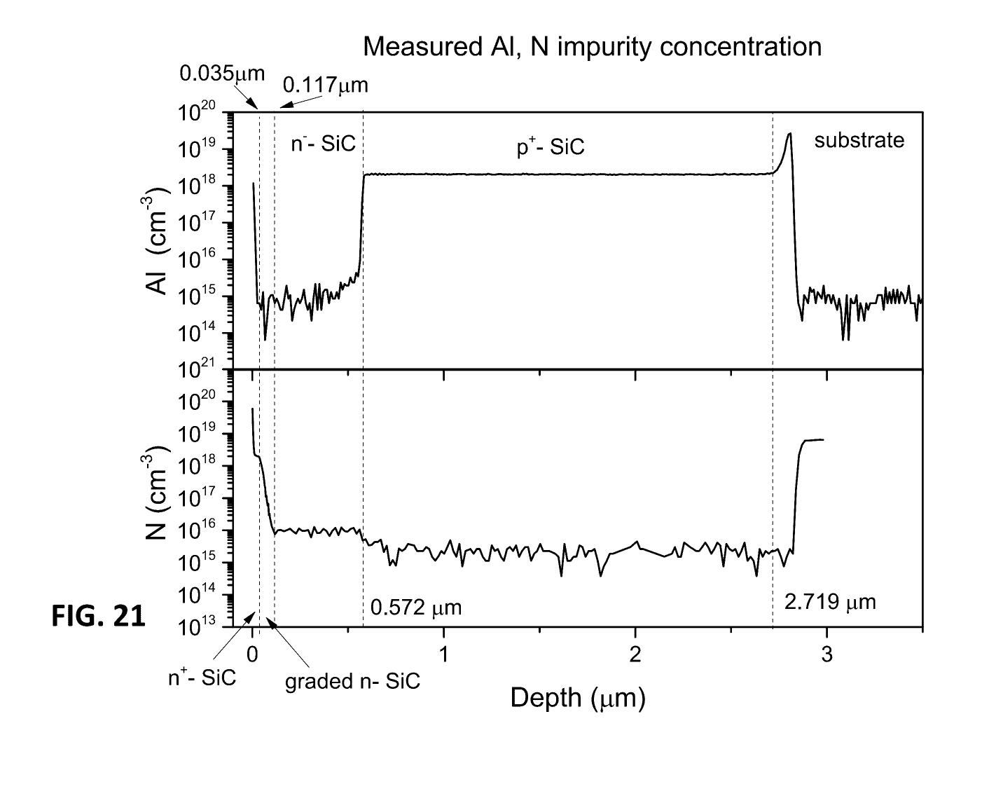

This approach can also be employed for an alternate preferred embodiment p-p⁻-n structure 90 where the (third region) p-layer 94 is now illuminated as shown in FIG. 20. The preferred embodiment structure 90 includes a substrate 91 and a layer (or second region) 93 where multiplication occurs and an n-type layer (or first region) 92 is sandwiched between the p-layer 94 and the substrate 91. This case is analogous to the previous case except that the types of doping in the illuminated layer and region adjacent the substrate are now switched. While not shown, it is assumed that the device is properly biased at the operating point of interest for detection. The choice of which structure to employ may be influenced by the semiconductor material selected and its properties. For example, as the ionization rate of holes is ˜10× larger than that of electrons for 4H—SiC an illuminated n-layer is desirable to fully absorb photons having energies much greater than the band gap and generate holes for multiplication within the multiplication region of the avalanche photodiode. However, for silicon, that also has a high density of surface states, the ionization rate of electrons is ˜100× greater than that of holes so that an illuminated p-layer is likely more desirable.

The use of a doped and conductive wider band gap semiconductor in the illuminated layer (or third region) within a heterojunction N-n⁻-p or P-p⁻-n can greatly reduce complexity of design, where by convention the capital letter refers to the wider band gap semiconductor material. This is due to the fact that the wider band gap layer may be selected so as to be transparent to the photons at the short wavelength range of interest such that the photons are absorbed in the high electric field i-region near the hetero-interface. As a result, the carriers generated by photons in the short wavelength range of interest will be collected more efficiently by drift over a comparable homojunction detector. For the case of polar semiconductors such as n-AlₓGa₁₋ₓN and SiC there is also an advantage associated with positive polarization induced charge at the AlGaN/SiC heterointerface in a n-AlGaN n⁻-SiC/p-SiC heterojunction detector, as it will act to prevent the depletion of the n-AlGaN layer and prevent punch-through to the metal contact. However, as lattice mismatch at hetero-interfaces can result in the generation of defects that can result in deleterious dark current, the use of the n-layer in the N-n-n⁻-p (or correspondingly the p-layer in a P-p-p⁻-n) can act to suppress these effects by reducing the electric field at the hetero-interface. This design may also have lower excess noise due to the spatial separation of the principal absorption region (the n-layer for an N-n-n⁻-p) and the multiplication region (the n⁻-layer for an N-n-n⁻-p) within the diode.

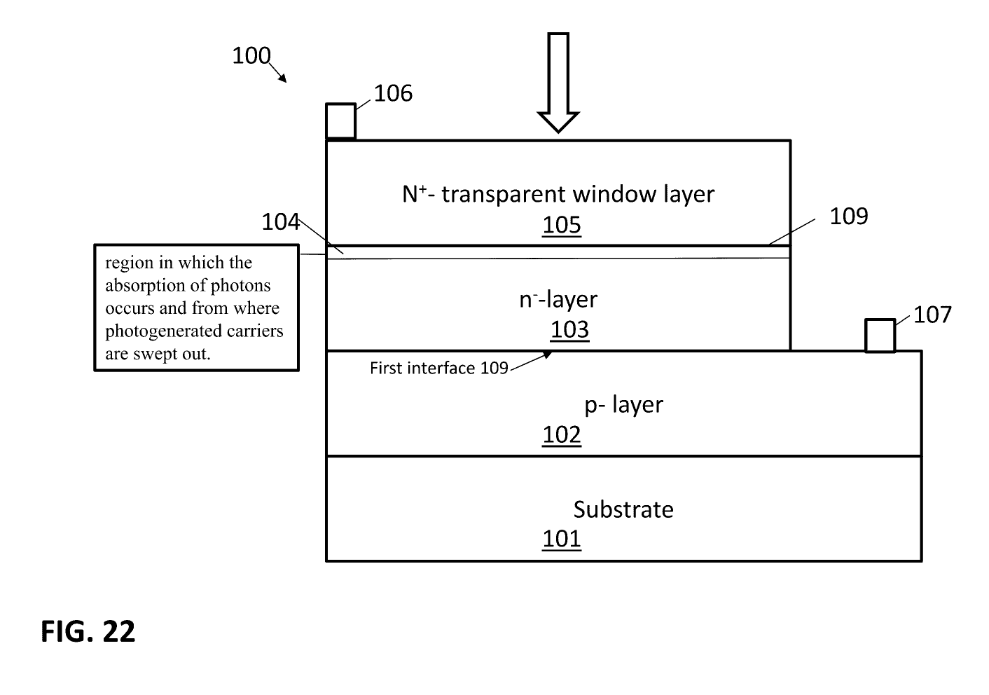

Referring now to FIG. 22, shown is preferred embodiment 100 comprising a substrate 101, p-layer 102, n⁻ layer 103 and transparent window layer 105, which is formed predominately of a N+ material, i.e., an n-type material with excess doping and transparent at the detection wavelength of interest potentially utilizing a wider band gap material than layer 103. Layer 105 is transparent at the predetermined photon energy range and is also suitable for making an operative connection to a contact 106. The preferred embodiment photodiode 100 eliminates or minimizes surface recombination of photogenerated carriers generated by photons having a predetermined energy range. The region 104 has a short absorption depth within an effective diffusion length of the surface or interface of the n⁻-layer for the photons having a predetermined energy range. The n⁻ layer or second region is formed of a semiconductor having a high surface or interface recombination velocity. The first semiconductor region 105 and the n⁻ layer 103 (second region) form a first interface 109 such that the second region is depleted at the interface between the second region and the transparent region at the reverse bias point of operation. The region 103 is depleted to include the region 104; and the depletion extends from the first interface through the absorption region 104 through the region denoted 103 at the operating bias. The depletion results in the creation of an electric field and photogenerated carriers are collected by drift and the photons at the predetermined energy are detected as current. The current will flow between the terminals 106 and 107.

Referring now to FIG. 23, shown is preferred embodiment 110 comprising a substrate 111, n-layer 112, p⁻ layer 113 and transparent window layer 115, which is formed predominately of a P+ material, i.e., an p-type material with excess doping and transparent at the detection wavelength of interest potentially utilizing a wider band gap material than layer 113. Layer 115 is transparent at the predetermined photon energy range and is also suitable for making an operative connection to a contact 116. The preferred embodiment photodiode 110 eliminates or minimizes surface recombination of photogenerated carriers generated by photons having a predetermined energy range. The absorption region 114 is within an effective diffusion length of the surface or interface for the photons having a predetermined energy range. The p⁻ layer or second region 113 is formed of a semiconductor having a high surface or interface recombination velocity. The first semiconductor region 115 and the p⁻ layer 113 (second region) form a first interface 119 such that the second region is depleted at the interface between the second region and the transparent region at the reverse bias point of operation. The region 113 is depleted to include the region 114; and the depletion extends from the first interface 119 through the absorption region 114 at the operating bias. The depletion results in the creation of an electric field and photogenerated carriers within the absorption region 114 are collected by drift and the photons at the predetermined energy are detected as current. The current will flow between the terminals 116 and 117.

FIG. 26 is a schematic diagram depicting the absorption depth, effective diffusion length and the depletion width. The second region comprises a semiconductor material having a band gap energy and the third region comprises semiconductor material having a band gap energy larger than the band gap energy of the second region. The third region is transparent at the predetermined photon energy range. Photons impinging the third region are absorbed in the second region generating carriers. The second region being configured such that biasing the photodiode results in depletion of the second region at the reverse bias point of operation from the first interface to (1) the absorption depth or (2) the sum of the absorption depth and the effective diffusion length from the second interface. Depletion occurring in the second region results in the creation of an electric field and photogenerated carriers are collected by drift. The depletion ranges as depicted in FIG. 26; shown by dashed lines.

It can thus be seen that the alternate preferred embodiments of the present invention provides an approach for realizing a highly efficient SPAD in DUV spectrum between 200-280 nm, as the key transducing element within a SPAD module is the avalanche photodiode. Currently system designers requiring high sensitivity and low noise UV detectors for spectroscopy and single photon counting have the option of employing PMTs or UV enhanced Si avalanche photodetectors. PMTs have significant shortcomings, including high cost (−$2000 with power supply and cooling), bulky packaging, susceptibility to magnetic fields, requiring high voltage for operation (>1000 V) and cooling for high sensitivity. UV enhanced Si avalanche photodetectors can provide high gain, but can have high dark current and significant long wavelength response that can make them suboptimal for applications such as biological agent detection. Commercially available Si based single photon counting detectors (SPADs) have not been specified for operation below 300 nm. The present invention provides an approach for developing a semiconductor based SPAD with efficient detection in DUV spectral range between 200-280 nm. The preferred embodiments are advantageous for system designers because:

The alternate preferred embodiments of the present invention can be operated at room temperature, while PMTs often require thermoelectric cooling depending upon the sensitivity required.

PMTs require the cathode detection material and dynode gain medium to be encased within a vacuum sealed tube. This packaging is inherently more fragile than that employed for semiconductor based detectors.

The alternate preferred embodiments of the present invention provide a novel approach for increasing the deep ultraviolet response in a SiC based avalanche photodiode in a more robust fashion. This is accomplished by extending the depletion region of the illuminated n-type doped layer under high reverse bias where the device exhibits substantial gain. It also leverages the inhomogeneous gain associated with strong absorption of these DUV photon at the illuminated semiconductor surface and higher ionization rate of holes over electrons within SiC. This design also takes advantage of these phenomena to realize low excess noise in the spectral range of interest via single carrier multiplication within the developed structure without the use of a charge layer. This can lead to further improvements in detection efficiency over a conventional separate-absorption-charge-multiplication structure.

As used herein (in the drawings, specification. abstract and claims), the term “light” means electromagnetic radiation, unless specifically noted to the contrary. In the drawings, the symbol λ means electromagnetic radiation. Within the light spectrum, the solar blind region refers to the region of the light spectrum wherein, due to absorption of sunlight by the atmosphere, the potential interfering effect of sunlight does not occur; i.e., normally considered to be less than 280 nm at low elevations.

As used herein, the terminology “layer” includes “region” and is not limited to a single thickness of a material covering or overlying another part or layer, but encompasses a region having a variety of configurations and/or thicknesses.

As used herein, the terminology “multiplication layer” or “multiplication region” means a layer or layers or region in which the carriers predominantly multiply. The carriers may be either holes and/or electrons.

As used herein, the terminology “absorption layer”, “absorption region”, “absorber”, “absorber region” means a layer or layers or region in which photons are predominantly absorbed and photogenerated carriers created. Absorption and multiplication may occur in the same layers (or regions).

As used herein the term P in bold face represents the magnitude of the polarization vector.

As used herein, the terminology “potential” with respect to “electrostatic potential” refers to voltage potential.

As used herein, the scalar projection of the polarization vector P on the vector G (designating the growth direction), which can also be referred to as the scalar resolute or scalar component of P in the direction of the growth direction G, is given by:

S=|P|cos θ=P·Ĝ

where the operator (·) denotes the dot product, Ĝ is the unit vector in the direction of the Growth Vector G, |P| is the magnitude of the polarization vector P, and θ is the angle between vectors P and G. Note that the scalar projection is equal to the length or magnitude of the projection of P onto G, with a minus sign if the projection has an opposite direction with respect to G. With reference to the right side of the above equation, multiplying the scalar projection of P on G by Ĝ converts it into the foregoing projection, also referred to as the vector projection of P on G.

As used herein, the terminology “spectrally inhomogeneous gain” in a representative structure is shown in FIG. 15. FIG. 15 shows that photons of different wavelengths generate carriers that have different gain associated with them. For the n-i-p structure modelled, the gain at 200 nm is ˜310 while at 360 nm it is ˜75. In contrast for a p-i-n structure the opposite is the case, gain at 360 nm is ˜6× greater than gain at 200 nm. This phenomena is related to 1) the ionization rate of the principal carrier that is being multiplied in the gain region and 2) where the photons are absorbed within the structure that effects the distance photogenerated carriers travel inside the gain region. As holes have a higher ionization rate that electrons in 4H—SiC and deep ultraviolet photons are absorbed very close to the surface, an n-i-p device operating at these wavelengths has higher gain. This phenomenon is partially responsible for the emerging 212 nm peak observed in FIG. 13 at biases above 130V where one starts seeing effects of gain.

As used herein, the terminology InGaN, (In)GaN or InₓGₐ₁₋ₓN refers to the binary compound GaN or a ternary compound of InGaN having arbitrary mole fraction of InN.

As used herein, the terminology AlGaN, (Al)GaN or AlₓGₐ₁₋ₓN refers to the binary compound GaN (when x=0) or a ternary compound of AlGaN having arbitrary mole fraction of AlN.

As used herein, the terminology (Al)(In)GaN or (In)(Al)GaN refers to the binary compound GaN or ternary or quaternary III-Nitride semiconductor compound having arbitrary mole fractions of InN and/or AlN.

As used herein, the terminology “approximately” means something is almost, but not completely, accurate or exact; roughly.

As used herein, the terminology (In)AlN refers to the binary compound AlN or ternary compound having arbitrary mole fractions of InN.

As used herein, the terminology “potential” with respect to “electrostatic potential” refers to voltage potential.

As used herein the terminology “p-metal contact” means a metal contact to a p-type layer.

As used herein the terminology “n-metal contact” means a metal contact to an n-type layer.

As used herein, the terminology p layer means p-type layer.

As used herein, the terminology n+ layer means an n-type layer with increased doping concentration.

As used herein, the terminology p+ layer means a p-type layer with increased doping concentration.

As used herein, the terminology n⁻-layer has sufficiently low doping so that it is mostly depleted at zero bias

As used herein, the terminology p⁻-layer has sufficiently low doping so that it is mostly depleted at zero bias

As used herein, the terminology N-layer refers to a layer having n-type doping and is transparent at the wavelength of interest for detection

As used herein, the terminology P-layer refers to a layer having p-type doping and is transparent at the wavelength of interest for detection

As used herein, the absorption depth refers to a thickness within a layer wherein 1−1/e (e=natural logarithm=0.368); i.e., approximately 63% of the photons at the detection wavelength of interest are absorbed according to Beer's Law.

As used herein the effective diffusion length is the distance from the depth from the absorption depth at which the carriers are created to the distance such that a majority of carriers reach the depletion region prior to recombining. Diffusion is the net movement of carriers from a region of high concentration to a region of low concentration of carriers.

It is understood that an absorption depth and the effective diffusion length (see FIG. 26) are parameters that describe a distribution of carriers and that the initial distribution is defined by the photon absorption probability according to, for example, Beer's Law, as appreciated by persons of ordinary skill in the art.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the claims.

1. A method of making a photodiode which eliminates or minimizes surface recombination of photogenerated carriers generated by photons having a predetermined energy range comprising:
providing a substrate;
providing a first semiconducting region operatively associated with the substrate suitable for forming a contact thereon;
providing a first contact operatively associated with the first semiconducting region;
providing a second region comprising an absorption region for the photons having a predetermined energy range; the second region being formed of a semiconductor having a high surface or interface recombination velocity;
providing a third semiconducting region transparent at the predetermined photon energy range suitable for making an operative connection to a second contact;
providing a second interface between the second and third regions upon which the photons impinge;
the first semiconductor region and the second region forming a first interface such that the second region is depleted at the reverse bias point of operation; the depletion width in the second region varying with applied reverse bias; the minimal depletion width extending from the first interface to at least the sum of the absorption depth and the effective diffusion length from the second interface; the photodiode being configured such that biasing the photodiode results in depletion of the second region;
whereby the depletion results in the creation of an electric field and photogenerated carriers are collected by drift.

2. The method of claim 1 wherein the second region is an absorption multiplication region where photogenerated carriers multiply due to impact ionization in the electric field and wherein the depletion width in the second region extends from the first interface to the second interface.

3. The method of claim 1 wherein the third region adjacent to the second region having a total polarization, the third region comprising a crystalline structure having a growth direction and the second region have a different total polarization having a magnitude and direction, the second and third regions forming an interface therebetween,

4. The method of claim 1 wherein the material or materials forming the second region comprises one or more of silicon carbide, silicon, germanium, and indium phosphide, and the material or materials forming the third region comprises one or more of gallium nitride, indium gallium nitride, aluminum gallium nitride, indium aluminum gallium nitride, indium aluminum nitride, boron aluminum nitride, boron aluminum gallium nitride, aluminum nitride, boron nitride, and indium nitride, silicon carbide, silicon, zinc oxide, magnesium oxide, magnesium zinc oxide, zinc sulfide, cadmium sulfide, cadmium zinc sulfide, magnesium zinc sulfide, cadmium telluride, cadmium zinc telluride, and other Group III-V and Group II-VI materials.

5. The method of claim 1 wherein the first region comprises silicon carbide with an aluminum doping in the range from 1×10¹⁸ cm⁻³-1×10¹⁹ cm⁻³ and wherein the second region comprises silicon carbide with a nitrogen atom doping in the range from 1×10¹⁵ cm⁻³ to 1×10¹⁶ cm⁻³ and a thickness in the range from 250-1000 nm and wherein the third region comprises aluminum gallium nitride with an aluminum to gallium composition ratio in the range from 80-90% aluminum and an electron carrier concentration in the range of 1×10¹⁸ cm⁻³-1×10¹⁹ cm⁻³ and a thickness in the range of 50-470 nm.

6. The method of claim 1 further comprising an intermediate region between the second and third regions, and wherein the second region has a first total polarization; the intermediate region has a second total polarization greater than the magnitude of the first total polarization; and wherein the third region has a third total polarization, wherein the second and intermediate regions form a first interface charge and wherein the polarizations of the intermediate and third regions form a second interface charge; the first and second interface charges creating electrostatic potential barriers to carriers of differing energy levels;
whereby the electrostatic potential barriers may be modified by modifying one of the thickness of the intermediate region, the voltage differential or reverse bias across the photodiode, or the material composition or doping of the intermediate, second or third regions to define a predetermined photon energy range.

7. The method of claim 6 wherein the predetermined photon energy range of the photodiode is modified by altering the electrostatic potential barrier by changing the thickness of the intermediate region in association with the first and second interface charges.

8. The method of claim 6 wherein the intermediate region is sufficiently thick so as to preclude the tunneling of carriers between the third region and the second region.

9. The method of claim 6 wherein the predetermined photon energy range of the photodiode is modified by altering the electrostatic potential barrier by adjusting the reverse bias across the photodiode.

10. The method of claim 6 wherein the electrostatic potential barrier can be modified by adjusting the interface charge by adding donors which are ionized to increase the net positive charge or by adjusting the interface charge by adding acceptors which are ionized to increase the net negative charge.

11. The method of claim 6 wherein the predetermined wavelength range is less than 260 nanometers and wherein the first and second regions comprise silicon carbide, the intermediate region comprises one of aluminum nitride and aluminum gallium nitride and the third region is suitable for forming an n-metal contact thereon and comprises aluminum gallium nitride of higher gallium content than the intermediate region.

12. A photodiode that eliminates or minimizes surface recombination of photogenerated carriers generated by photons having a predetermined energy range comprising:
a substrate;
a first semiconducting region operatively associated with the substrate suitable for forming a contact thereon;
a first contact operatively associated with the first semiconducting region;
a second region comprising an absorption region for the photons having a predetermined energy range; the second region being formed of a semiconductor having a high surface or interface recombination velocity;
a third semiconducting region transparent at the predetermined photon energy range suitable for making an operative connection to a second contact; the second and third regions forming a second interface upon which photons impinge;
the first semiconductor region and the second region forming a first interface; the second region being configured such that biasing the photodiode results in depletion of the second region at the reverse bias point of operation from the first interface to at least one of the absorption depth and the sum of the absorption depth and effective diffusion length from the second interface;
whereby the depletion results in the creation of an electric field and photogenerated carriers are collected by drift.

13. The photodiode of claim 12 wherein the second region is an absorption multiplication region where photogenerated carriers multiply due to impact ionization in the electric field and wherein the depletion in the second region extends from the first interface to the second interface.

14. The photodiode of claim 12 wherein the third region adjacent to the second region having a total polarization, the third region comprising a crystalline structure having a growth direction and the second region have a different total polarization having a magnitude and direction, the second and third regions forming an interface therebetween.

15. The photodiode of claim 12 wherein the first region comprises silicon carbide with an aluminum doping in the range from 1×10¹⁸ cm⁻³-1×10¹⁹ cm⁻³ and wherein the second region comprises silicon carbide with a nitrogen atom doping in the range from 1×10¹⁵ cm⁻³ to 1×10¹⁶ cm⁻³ and a thickness in the range from 250-1000 nm and wherein the third region comprises aluminum gallium nitride with an aluminum to gallium composition ration in the range from 80-90% aluminum and an electron carrier concentration in the range of 1×10¹⁸ cm⁻³-1×10¹⁹ cm⁻³ and a thickness in the range of 50-470 nm.

16. A photodiode that eliminates or minimizes surface recombination of photogenerated carriers generated by photons having a predetermined energy range comprising:
a substrate;
a first semiconducting region operatively associated with the substrate suitable for forming a contact thereon;
a first contact operatively associated with the first semiconducting region;
a second region comprising an absorption region for the photons having a predetermined energy range; the second region being formed of a semiconductor having a high surface or interface recombination velocity;
a third semiconducting region transparent at the predetermined photon energy range suitable for making an operative connection to a second contact; the second and third regions forming a second interface upon which the photons impinge;
the first semiconductor region and the second region forming a first interface such that the second region is depleted at the reverse bias point of operation; the depletion width in the second region varying with applied reverse bias; the minimal depletion width extending from the first interface to at least the sum of the absorption depth and the effective diffusion length from the second interface; the photodiode being configured such that biasing the photodiode results in depletion of the second region;
whereby the depletion results in the creation of an electric field and photogenerated carriers are collected by drift.

17. The photodiode of claim 16 wherein the second region is an absorption multiplication region where photogenerated carriers multiply due to impact ionization in the electric field and wherein the depletion width in the second region extends from the first interface to the second interface.

18. The photodiode of claim 16 wherein the third region adjacent to the second region having a total polarization, the third region comprising a crystalline structure having a growth direction and the second region have a different total polarization having a magnitude and direction, the second and third regions forming an interface therebetween,

19. The photodiode of claim 16 wherein the first region comprises silicon carbide with an aluminum doping in the range from 1×10¹⁸ cm⁻³-1×10¹⁹ cm⁻³ and wherein the second region comprises silicon carbide with a nitrogen atom doping in the range from 1×10¹⁵ cm⁻³ to 1×10¹⁶ cm⁻³ and a thickness in the range from 250-1000 nm and wherein the third region comprises aluminum gallium nitride with an aluminum to gallium composition ration in the range from 80-90% aluminum and an electron carrier concentration in the range of 1×10¹⁸ cm⁻³-1×10¹⁹ cm⁻³ and a thickness in the range of 50-470 nm.

20. The photodiode of claim 16 wherein the second region comprises a semiconductor material having a band gap energy and wherein the third region comprises a semiconductor material having a band gap energy larger than the second region, and is transparent at the predetermined photon energy range;
the third region providing the electrical contact and extending the electrical field through the second region such that photons in a predetermined energy range impinging on the third region are absorbed in the second region generating carriers.
